(19) United States
(12) Patent Application Publication
(10) Pub. No.: US 2026/0013139 A1
(43) Pub. Date: Jan. 8, 2026

(54) MEMORY DEVICE HAVING SEPARATED PASS TRANSISTORS

(71) Applicant: Samsung Electronics Co., Ltd., Suwon-si (KR)

(72) Inventors: Hanmin NAM, Suwon-si (KR); Jeunghwan Park, Suwon-si (KR)

(73) Assignee: Samsung Electronics Co., Ltd., Suwon-si (KR)

(21) Appl. No.: 19/224,053

(22) Filed: May 30, 2025

(30) Foreign Application Priority Data
Jul. 3, 2024 (KR) 10-2024-0087807

(51) Int. Cl. H10B 43/35; H10B 43/27

(52) U.S. Cl. CPC H10B 43/35; H10B 43/27

(57) ABSTRACT

A memory device includes a memory block including a plurality of cell strings coupled between a first P-type substrate and a plurality of memory blocks, a first pass transistor circuit including a plurality of first pass transistors configured to drive first gate lines from among the plurality of gate lines, and a second pass transistor circuit including a plurality of second pass transistors configured to drive second gate lines from among the plurality of gate lines. The plurality of cell strings are coupled with the plurality of gate lines including a string selection line, a plurality of word lines, and a ground selection line. The plurality of gate lines are stacked in a vertical direction. The first pass transistor circuit is disposed in a pocket P-type well area formed on the first P-type substrate. The second pass transistor circuit is disposed on a second P-type substrate.

### CROSS-REFERENCE TO RELATED APPLICATIONS

This application claims benefit of priority under 35 U.S.C. § 119 to Korean Patent Application No. 10-2024-0087807, filed on Jul. 3, 2024, in the Korean Intellectual Property Office, the disclosure of which is incorporated by reference herein in its entirety.

### BACKGROUND

The present disclosure concept relates generally to semiconductor memory devices, and more particularly, to memory devices in which some pass transistors are formed on a semiconductor substrate.

Recently, at least due to multi-functionalization of information communication devices, there has been an increased demand for larger capacity and/or higher integration of memory devices. However, as memory cell sizes decrease to provide for the demanded higher integration, a complexity of operation circuits and/or wiring structures included in memory devices for operations and electrical connections of the memory device may have increased. Accordingly, there is need for a memory device with an increased integration and advantageous electrical properties. A possible approach for potentially achieving improvements in storage capacities and/or integration of memory devices may include the use of a nonvolatile memory device in which memory cells are stacked in a three-dimensional (3D) structure (e.g., a 3D NAND flash memory).

In a 3D NAND flash memory, relatively large capacities of memory blocks may be achieved by increasing the number of word lines stacked in a vertical direction with respect to a substrate. However, as the number of pass transistors connected to word lines increases, chip sizes of the memory devices may also increase.

### SUMMARY

One or more example embodiments of the present disclosure provide memory devices in which some of pass transistors are formed on a P-type semiconductor substrate, not in a pocket P-type well area, and as a result, chip sizes of the memory device may be reduced, when compared to related memory devices.

According to an aspect of the present disclosure, a memory device includes a memory block, a first pass transistor circuit, and a second pass transistor circuit. The memory block includes a plurality of cell strings coupled between a first P-type substrate and a plurality of bit lines. The plurality of cell strings are coupled with a plurality of gate lines including a string selection line, a plurality of word lines, and a ground selection line. The plurality of gate lines are stacked in a vertical direction. The first pass transistor circuit includes a plurality of first pass transistors configured to drive first gate lines from among the plurality of gate lines. The second pass transistor circuit includes a plurality of second pass transistors configured to drive second gate lines from among the plurality of gate lines. The first pass transistor circuit is disposed in a pocket P-type well area formed on the first P-type substrate. The second pass transistor circuit is disposed on a second P-type substrate.

According to an aspect of the present disclosure, a memory device includes a memory block, a first pass transistor circuit, and a second pass transistor circuit. The memory block includes a plurality of cell strings coupled between a first P-type substrate and a plurality of bit lines. The plurality of cell strings are configured to be selected by a string selection line. Each of the plurality of cell strings includes a plurality of word lines stacked in a vertical direction. The first pass transistor circuit includes a plurality of first pass transistors configured to drive the string selection line and each of the plurality of word lines. The second pass transistor circuit includes a second pass transistor configured to drive the string selection line. The first pass transistor circuit is disposed in a pocket P-type well area formed on the first P-type substrate. The second pass transistor circuit is disposed on a second P-type substrate. The pocket P-type well area is formed in a deep N-type well area formed on the first P-type substrate and is biased with a negative voltage. The deep N-type well area is biased with a positive voltage. The second P-type substrate is biased with a ground voltage.

According to an aspect of the present disclosure, a memory device includes a memory block, a first dummy word line between a string selection line and a plurality of word lines, a first pass transistor circuit, and a second pass transistor circuit. The memory block includes a plurality of cell strings coupled between a first P-type substrate and a plurality of bit lines. The plurality of cell strings includes the string selection line, the plurality of word lines, and a ground selection line. The plurality of cell strings are stacked in a vertical direction. The first pass transistor circuit includes a plurality of first pass transistors configured to drive each of the string selection line, the plurality of word lines, and the ground selection line. The second pass transistor circuit includes a second pass transistor configured to drive the ground selection line, and a first plurality of pass transistors configured to drive the first dummy word line. The first pass transistor circuit is disposed in a pocket P-type well area formed on the first P-type substrate. The second pass transistor circuit is disposed on a second P-type substrate.

According to an aspect of the present disclosure, a memory device includes a memory block, a first pass transistor circuit, and a second pass transistor circuit. The memory block includes a plurality of cell strings coupled between a first P-type substrate and a plurality of bit lines. The plurality of cell strings includes a string selection line, a plurality of word lines, at least one dummy word line, and a ground selection line. The plurality of cell strings are stacked in a vertical direction. The first pass transistor circuit includes a plurality of first pass transistors configured to drive each of the string selection line, the plurality of word lines, the at least one dummy word line, and the ground selection line. The second pass transistor circuit includes a second pass transistor configured to drive the at least one dummy word line, and a plurality of pass transistors configured to drive the string selection line of the plurality of cell strings. The first pass transistor circuit is disposed in a pocket P-type well area formed on the first P-type substrate. The second pass transistor circuit is disposed on a second P-type substrate.

According to an aspect of the present disclosure, a memory device includes a first memory block and a second memory block, a first pass transistor circuit, and second pass transistor circuits. Each of the first memory block and the second memory block include a plurality of cell strings coupled between a first P-type substrate and a plurality of bit lines. The plurality of cell strings includes a string selection line, a plurality of word lines, and a ground selection line. The plurality of cell strings are stacked in a vertical direction. The first pass transistor circuit is configured to drive the plurality of word lines of the first memory block and the second memory block. The first pass transistor circuit includes a first plurality of pass transistors configured to drive each of the string selection line and the ground selection line of the first memory block and the second memory block. The second pass transistor circuits are configured to drive the string selection line of each of the first memory block and the second memory block. The first pass transistor circuit is disposed in a P-type well area formed on the first P-type substrate between the first memory block and the second memory block. The second pass transistor circuits are disposed on a second P-type substrate on edges of the first memory block and the second memory block in a first direction.

In some embodiments, the P-type well area is formed in a deep N-type well area formed on the first P-type substrate and is biased with a negative voltage, the deep N-type well area is biased with a positive voltage, and the second P-type substrate is biased with a ground voltage.

In some embodiments, the second pass transistor circuits further comprise a second plurality of pass transistors configured to drive the ground selection line of the plurality of cell strings.

In some embodiments, each of the first memory block and the second memory block further comprise a dummy word line between the ground selection line and the plurality of word lines, and the second pass transistor circuits further comprise a third plurality of pass transistors configured to drive the dummy word line.

In some embodiments, the first P-type substrate and the second P-type substrate are a same substrate.

In some embodiments, the first P-type substrate is different from the second P-type substrate.

According to an aspect of the present disclosure, a memory device includes a first memory block and a second memory block, first pass transistor circuits, and a second pass transistor circuit. Each of the first memory block and the second memory block includes a plurality of cell strings coupled between a first P-type substrate and a plurality of bit lines. The plurality of cell strings include a string selection line, a plurality of word lines, and a ground selection line. The plurality of cell strings are stacked in a vertical direction. The first pass transistor circuits are configured to drive the plurality of word lines of the first memory block and the second memory block. The first pass transistor circuits include a first plurality of pass transistors configured to drive each of the string selection line and the ground selection line of the first memory block and the second memory block. The second pass transistor circuit is configured to drive the string selection line of each of the first memory block and the second memory block. The second pass transistor circuit includes a second plurality of pass transistors configured to drive the ground selection line of the plurality of cell strings. The second pass transistor circuit is disposed on the first P-type substrate on edges of the first memory block and the second memory block. The first pass transistor circuits are disposed in a P-type well area formed on a second P-type substrate between the first memory block and the second memory block.

According to an aspect of the present disclosure, a memory device includes a plurality of memory blocks, a first pass transistor circuit, and second pass transistor circuits. The plurality of memory blocks includes a first memory block, a second memory block, a third memory block, and a fourth memory block. Each memory block of the plurality of memory blocks includes a plurality of cell strings coupled between a first P-type substrate and a plurality of bit lines. The plurality of cell strings are configured to be selected by a string selection line. The plurality of memory blocks are disposed in a first direction. Each of the plurality of cell strings includes a plurality of word lines stacked in a vertical direction and a first dummy word line between the string selection line and the plurality of word lines. The first pass transistor circuit is configured to drive the plurality of word lines of the plurality of memory blocks. The second pass transistor circuits are configured to drive string selection lines of the plurality of memory blocks. The second pass transistor circuits include a first plurality of pass transistors configured to drive the first dummy word line and a second plurality of pass transistors configured to drive a ground selection line of the plurality of cell strings. The first pass transistor circuit is disposed in a pocket P-type well area formed on the first P-type substrate between the second memory block and the third memory block. The second pass transistor circuits are disposed on second P-type substrates between the first memory block and the second memory block and between the third memory block and the fourth memory block.

Additional aspects may be set forth in part in the description which follows and, in part, may be apparent from the description, and/or may be learned by practice of the presented embodiments.

### BRIEF DESCRIPTION OF DRAWINGS

The above and other aspects, features, and advantages of certain embodiments of the present disclosure may be more apparent from the following description taken in conjunction with the accompanying drawings, in which:

FIG. 1 is a block diagram schematically illustrating a memory device, according to embodiments;

FIG. 2 is a diagram schematically illustrating a structure of the memory device illustrated in FIG. 1, according to embodiments;

FIG. 3 is an equivalent circuit diagram of the memory block illustrated in FIG. 1, according to embodiments;

FIG. 4 is a diagram for describing a row decoder and a pass transistor circuit, according to embodiments;

FIG. 5 is a diagram for describing a memory device including a pass transistor circuit, according to embodiments;

FIG. 6 is a cross-sectional view schematically illustrating the memory device including the pass transistor circuit, which is illustrated in FIG. 5, according to embodiments;

FIGS. 7 and 8 are diagrams for describing an area occupied by the pass transistor circuit illustrated in FIG. 5, according to embodiments;

FIGS. 9A and 9B are diagrams for describing a memory device including a pass transistor circuit, according to embodiments;

FIG. 10 is a diagram for describing a memory device including a pass transistor circuit, according to embodiments;

FIG. 11 is a diagram for describing a memory device including a pass transistor circuit, according to embodiments;

FIG. 12 is a diagram for describing a memory device including a row decoder and a pass transistor circuit, according to embodiments;

FIG. 13 is a diagram for describing the memory device including the pass transistor circuit illustrated in FIG. 12, according to embodiments;

FIG. 14 is a diagram for describing a memory device, according to embodiments;

FIG. 15 is a block diagram illustrating an example in which a memory device is applied to a solid-state drive (SSD) system, according to embodiments; and

FIG. 16 is a block diagram of a system for describing an electronic device including a semiconductor integrated circuit, according to embodiments.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “upper,” “middle”, “lower”, and the like may be replaced with terms, such as “first,” “second,” third” to be used to describe relative positions of elements. The terms “first,” “second,” third” may be used to describe various elements but the elements are not limited by the terms and a “first element” may be referred to as a “second element”. Alternatively or additionally, the terms “first”, “second”, “third”, and the like may be used to distinguish components from each other and do not limit the present disclosure. For example, the terms “first”, “second”, “third”, and the like may not necessarily involve an order or a numerical meaning of any form.

As used herein, when an element or layer is referred to as “covering”, “overlapping”, or “surrounding” another element or layer, the element or layer may cover at least a portion of the other element or layer, where the portion may include a fraction of the other element or may include an entirety of the other element. Similarly, when an element or layer is referred to as “penetrating” another element or layer, the element or layer may penetrate at least a portion of the other element or layer, where the portion may include a fraction of the other element or may include an entire dimension (e.g., length, width, depth) of the other element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

The embodiments herein may be described and illustrated in terms of blocks, as shown in the drawings, which carry out a described function or functions. These blocks, which may be referred to herein as units or modules or the like, or by names such as device, logic, circuit, controller, counter, comparator, generator, converter, or the like, may be physically implemented by analog and/or digital circuits including one or more of a logic gate, an integrated circuit, a microprocessor, a microcontroller, a memory circuit, a passive electronic component, an active electronic component, an optical component, and the like.

In the present disclosure, the articles “a” and “an” are intended to include one or more items, and may be used interchangeably with “one or more.” Where only one item is intended, the term “one” or similar language is used. For example, the term “a processor” may refer to either a single processor or multiple processors. When a processor is described as carrying out an operation and the processor is referred to perform an additional operation, the multiple operations may be executed by either a single processor or any one or a combination of multiple processors.

As used herein, each of the terms “Si₃N₄”, “SiO₂”, and the like may refer to a material made of elements included in each of the terms and is not a chemical formula representing a stoichiometric relationship.

Hereinafter, various embodiments of the present disclosure are described with reference to the accompanying drawings.

A memory device described in the present disclosure may include a plurality of memory blocks having a three-dimensional (3D) structure, and each of the plurality of memory blocks may include NAND flash memory cells. In a memory block having a 3D structure, due to various factors (e.g., an electrical charge), it may be difficult to set a setup speed of selection lines to be substantially similar to and/or the same (e.g., identical) as a setup speed of word lines. Non-uniform setup speeds of the selection lines may cause a decrease in timing margins of operations (e.g., program operations, read operations, or erase operations) of the memory device and/or degradation in the reliability of data. Hereinafter, a memory device is provided by which signal setup speeds of selection lines connected to pass transistors may be improved and/or chip sizes may be reduced, when compared to related memory devices. For convenience of explanation, the memory device may also be referred to as a nonvolatile memory (NVM) device.

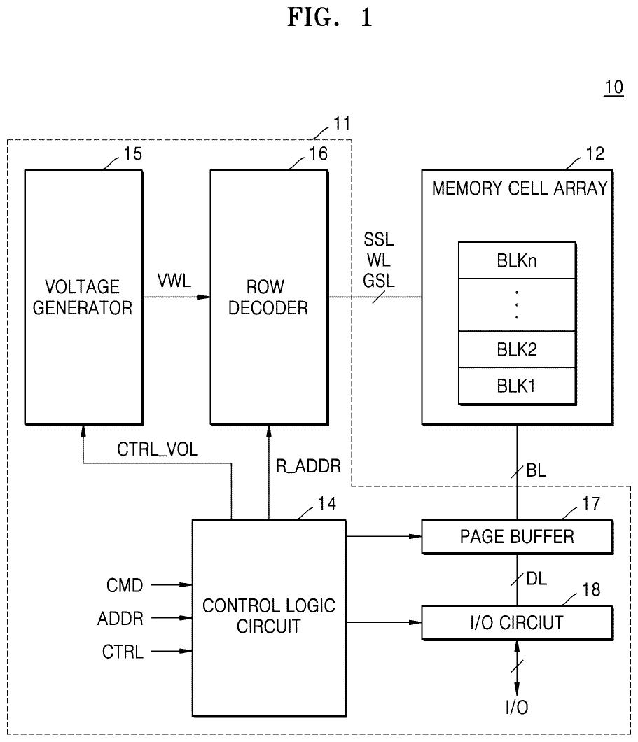

FIG. 1 is a block diagram schematically illustrating a memory device, according to embodiments.

Referring to FIG. 1, the memory device 10 may include a peripheral circuit 11 and a memory cell array 12, and the peripheral circuit 11 may include a control logic circuit 14, a voltage generator 15, a row decoder 16, a page buffer 17, and an input/output (I/O) circuit 18. In an embodiment, the peripheral circuit 11 may further include an I/O interface connected to an external device, such as, but not limited to, a memory controller.

The memory cell array 12 may be connected to word lines WL, string selection lines SSL, ground selection lines GSL, and bit lines BL. The memory cell array 12 may be connected to the row decoder 16 through the word lines WL, the string selection lines SSL, and the ground selection lines GSL, and may be connected to the page buffer 17 through the bit lines BL. The memory cell array 12 may include a plurality of memory blocks (e.g., a first memory block BLK1, a second memory block BLK2, to an n-th memory block BLKn, hereinafter generally referred to as BLK, where n is a positive integer greater than one (1)), and each of the plurality of memory blocks BLK may include a plurality of NAND flash memory cells. The memory cell array 12 may include a 3D memory cell array including a plurality of cell strings.

The 3D memory cell array is formed in a monolithic manner on at least one memory cell array that has an active area on a silicon (Si) substrate and a circuit formed on or in the substrate as a circuit related to operations of the memory cells. The term monolithic may refer to layers of levels constructing the memory cell array being stacked right on layers of lower levels of the memory cell array. In an embodiment, the 3D memory cell array may include cell strings arranged in a vertical direction such that at least one memory cell is on another memory cell. The at least one memory cell may include a charge trap layer. U.S. Pat. Nos. 7,679,133, 8,553,466, 8,654,587, 8,559,235, and 9,536,970 disclose configurations of 3D memory arrays constructed with a plurality of levels and in which word lines and/or bit lines are shared between the plurality of levels, the disclosures of which are incorporated by reference herein in their entireties.

The plurality of memory blocks BLK may each include a plurality of memory cells and a plurality of selection transistors. The memory cells may be connected to the word lines WL, and the selection transistors may be connected to the string selection lines SSL or the ground selection line GSL. The memory cells in each of the plurality of memory blocks BLK may include single level cells configured to store one-bit data and/or multi-level cells configured to store M-bit data, where M is a positive integer greater than one (1).

The row decoder 16 may be configured to select one of the plurality of memory blocks BLK of the memory cell array 12, one of the word lines WL of the memory block that has been selected, one of the plurality of string selection lines SSL, and the ground selection line GSL.

The control logic circuit 14 may be configured to output various types of internal control signals for performance of program operations, read operations, erase operations, or the like on the memory cell array 12, based on a command CMD, an address ADDR, and a control signal CTRL transmitted from a memory controller, for example. The control logic circuit 14 may be configured to provide a row address R_ADDR to the row decoder 16, provide a column address to the I/O circuit 18, and provide a voltage control signal CTRL_VOL to the voltage generator 15. In such a manner, the control logic circuit 14 may generally control various operations in the memory device 10.

The page buffer 17 may be configured to operate as a write driver and/or a sense amplifier according to operation modes. In a write operation, the page buffer 17 may sense a bit line BL of a selected memory cell, under control of the control logic circuit 14. Sensed data may be stored in latches provided in the page buffer 17. The page buffer 17 may be configured to dump the data stored in the latches to the I/O circuit 18 through the data line DL, under control of the control logic circuit 14.

The I/O circuit 18 may be configured to temporarily store the command CMD, the address ADDR, and data DATA provided through an I/O line from the memory controller. The I/O circuit 18 may be configured to temporarily store write data of the memory device 10 and output the read data outside through the I/O line at a preset time point.

The voltage generator 15 may be configured to generate various kinds of voltages VWL for performing program operations, read operations, erase operations, or the like on the memory cell array 12, based on the voltage control signal CTRL_VOL. For example, the voltage generator 15 may be configured to generate a program voltage, a verification voltage, a read voltage, a pass voltage, an erase voltage, an erase verification voltage, a precharge voltage, an internal power voltage IVC, a negative voltage, or the like.

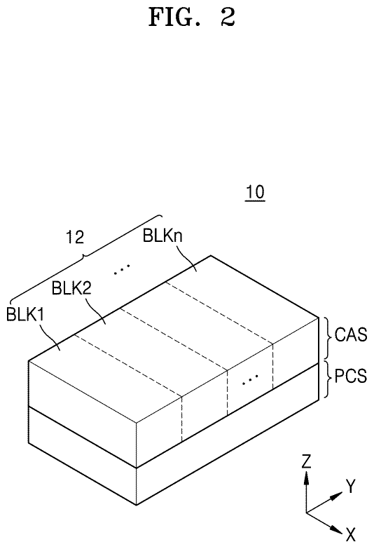

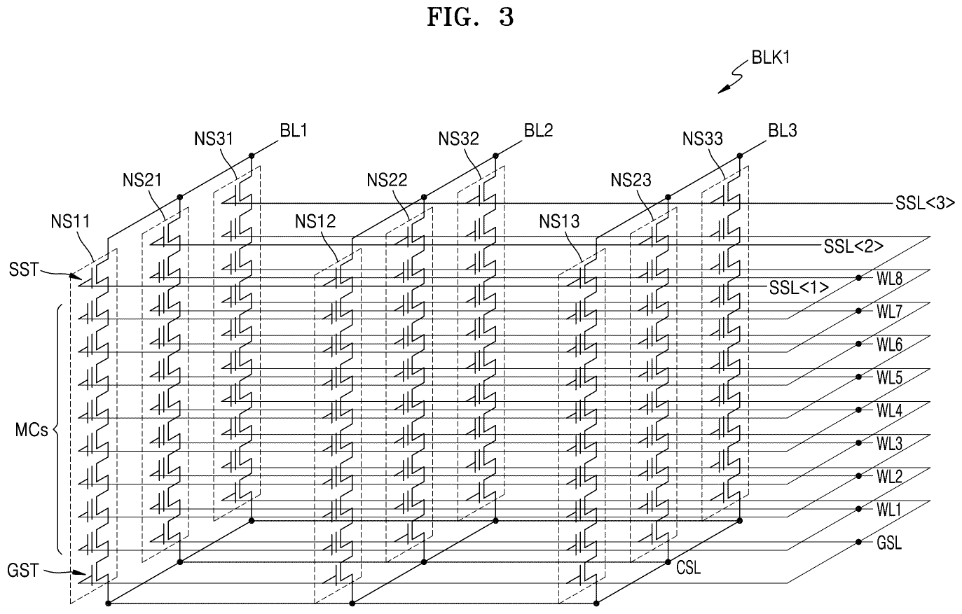

FIG. 2 schematically illustrates a structure of the memory device 10 shown in FIG. 1, according to embodiments. FIG. 3 illustrates an equivalent circuit diagram of the first memory block BLK1 shown in FIG. 1, according to embodiments.

Referring to FIG. 2, the memory device 10 includes a cell array structure CAS and a peripheral circuit structure PCS overlapping each other in a vertical direction (the Z direction). The cell array structure CAS may include and/or may be similar in many respects to the memory cell array 12 described with reference to FIG. 1. The peripheral circuit structure PCS may include and/or may be similar in many respects to the peripheral circuit 11 described with reference to FIG. 1. The cell array structure CAS may include the plurality of memory blocks BLK (e.g., the first memory block BLK1, the second memory block BLK2, to the n-th memory block BLKn). Each of the plurality of memory blocks BLK may include 3D arranged memory cells.

The memory block BLK1 illustrated in FIG. 3 may include and/or may be similar in many respects to the first memory block BLK1 described with reference to FIG. 1. However, the present disclosure is not limited in this regard, and the description of the first memory block BLK1 presented with reference to FIG. 3 may be applied to any of the other memory blocks of the plurality of memory blocks BLK of FIG. 1. Hereinafter, embodiments of the present disclosure are be described using the first memory block BLK1 as an example. For convenience of explanation, the first memory block BLK1 may also be referred to as the memory block BLK1. The memory block BLK1 may be and/or may include a 3D memory block formed in a 3D structure on a substrate. A plurality of memory cell strings included in the memory block BLK1 may be formed in a direction perpendicular to the substrate.

Referring to FIG. 3, the memory block BLK1 may include NAND strings (e.g., a first NAND string NS11, a second NAND string NS12, a third NAND string NS13, a fourth NAND string NS21, a fifth NAND string NS22, a sixth NAND string NS23, a seventh NAND string NS31, an eighth NAND string NS32, and a ninth NAND string NS33), word lines (e.g., a first word line WL1, a second word line WL2, a third word line WL3, a fourth word line WL4, a fifth word line WL5, a sixth word line WL6, a seventh word line WL7, and an eighth word line WL8), bit lines (e.g., a first bit line BL1, a second bit line BL2, and a third bit line BL3), a ground selection line GSL, string selection lines (e.g., a first string selection line SSL<1>, a second string selection line SSL<2>, and a third string selection line SSL<3>), and a common source line CSL. Although FIG. 3 illustrates that each of the first to ninth NAND strings NS11 to NS33 includes eight (8) memory cells MCs respectively connected to the first to eighth word lines WL1 to WL8, the present disclosure is not limited in this regard. That is, FIG. 3 is provided as only an example for understanding and is not intended to limit the present disclosure.

Each of the NAND strings (e.g., the first NAND string NS11) may include a string selection transistor SST, a plurality of memory cells MC, and a ground selection transistor GST connected in series. The string selection transistor SST may be connected to the first string selection line SSL<1> corresponding to the string selection transistor SST. The plurality of memory cells MC may be respectively connected to the first to eighth word lines WL1 to WL8 corresponding to the plurality of memory cells MC. The ground selection transistor GST may be connected to the ground selection line GSL. The string selection transistor SST may be connected to the first to third bit lines BL1 to BL3 corresponding to the string selection transistor SST, and the ground selection transistor GST may be connected to the common source line.

In the memory block BLK1, the first to eighth word lines WL1 to WL8 may be connected in common to memory cell transistors included in one layer. A same word line voltage may be provided to the memory cell transistors included in one layer. A plurality of string selection transistors SST formed in one layer may be connected to the plurality of string selection lines SSL<1> to SSL<3>. The ground selection transistors GST may be simultaneously controlled. That is, the ground selection transistors GST included in the memory block BLK1 may be controlled by the ground selection line GSL.

In some embodiments, in each NAND string one or more dummy memory cells may be provided between the string selection transistor SST and the memory cells MC. In each NAND string, one or more dummy memory cells may be provided between the ground selection transistor GST and the memory cells MC. In each NAND string, one or more dummy memory cells may be provided between the memory cells MC. The dummy memory cells may have a structure substantially similar to and/or the same (e.g., identical) as the structure of the memory cells MC, and may not be programmed (or program-inhibited) or may be programmed differently from the memory cells MC. For example, when the memory cells MC are programmed to have two (2) or more threshold voltage distributions, the dummy memory cells may be programmed to have a range of threshold voltage distribution or a less number of threshold voltage distribution compared with the memory cells MC.

In some embodiments, the string selection line SSL<1> may be connected to a gate of the string selection transistor SST, the first to eighth word lines WL1 to WL8 may be respectively connected to gates of the memory cell transistor, and each of dummy word lines may be connected to a gate of a dummy memory cell transistor, and the ground selection line GSL may be connected to a gate of the ground selection transistor GST. That is, the string selection line SSL<1>, the word lines WL1 to WL8, the dummy word lines, and the ground selection lines GSL may perform functions similar to gate lines. Accordingly, the string selection line SSL<1>, the first to eighth word lines WL1 to WL8, the dummy word lines, and the ground selection line GSL connected to the cell string may be referred to as the gate lines.

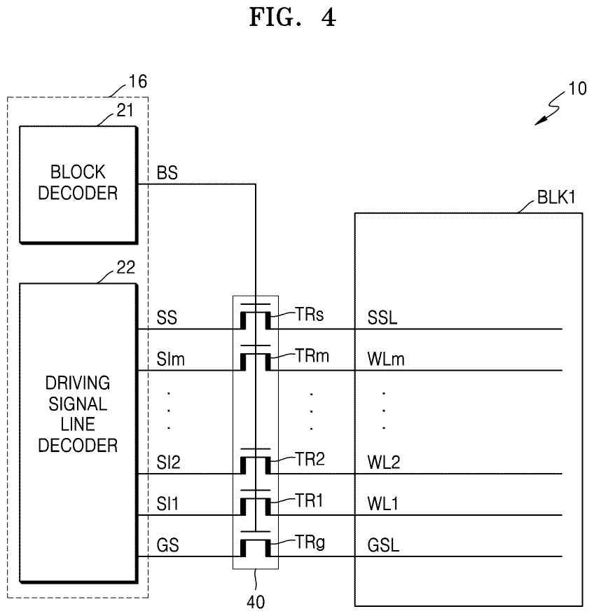

FIG. 4 is a diagram for describing the row decoder 16 and a pass transistor circuit 40, according to embodiments.

Referring to FIG. 4, the memory device may include the row decoder 16 and the pass transistor circuit 40 connected between the row decoder 16 and the memory block BLK1. The memory block BLK1 may include the ground selection line GSL, a plurality of word lines (e.g., a first word line WL1, a second word line WL2, to an m-th word line WLm, where m is a positive integer greater than one (1)), and the string selection line SSL. The row decoder 16 may include a block decoder 21 and a driving signal line decoder 22. The pass transistor circuit 40 may include a plurality of pass transistors (e.g., a string pass transistor TRs, a gate pass transistor TRg, a first pass transistor TR1, a second pass transistor TR2, to an m-th pass transistor TRm). The pass transistor circuit 40 may be provided in each of the plurality of memory blocks BLK, and the block decoder 21 and the driving signal line decoder 22 may be provided in common to the plurality of memory blocks BLK.

The block decoder 21 may be connected to the pass transistor circuit 40 through a block selection signal BS line. The block selection signal BS line may be connected to gates of the plurality of pass transistors of the pass transistor circuit 40 (e.g., the string pass transistor TRs, the first to m-th pass transistors TR1 to TRm, and the gate pass transistor TRg). For example, when a block selection signal BS provided through the block selection signal BS line is activated, the plurality of pass transistors (e.g., the string pass transistor TRs, the first to m-th pass transistors TR1 to TRm, and the gate pass transistor TRg) may be turned on, and thus, the memory block BLK1 may be selected.

The driving signal line decoder 22 may be connected to the pass transistor circuit 40 through a string selection line-driving signal line SS, word line-driving signal lines (e.g., a first word line-driving signal line SI1, a second word line-driving signal line SI2, to an m-th word line-driving signal line SIm), and a ground selection line-driving signal line GS. The string selection line-driving signal line SS, the first to m-th word line-driving signal lines SI1 to SIm, and the ground selection line-driving selection line GS may be respectively connected to sources of the plurality of pass transistors TRs, TR1 to TRm, and TRg. To simplify connection relationships, one string selection line-driving signal line SS is illustrated in the embodiment. However, in actuality, the string selection line-driving signal line SS may include a plurality of signal lines connected in correspondence to the plurality of string selection lines SSL<1> to SSL<3>.

The pass transistor circuit 40 may be connected to a memory block BLK1 through the ground selection line GSL, the plurality of word lines WL1 to WLm, and the string selection line SSL. The first to m-th pass transistors TR1 to TRm may be respectively connected to the first to m-th word line-driving signal lines SI1 to SIm corresponding to the plurality of word lines WL1 to WLm. The string pass transistor TRs may be configured to connect the string selection line SSL to the string selection line-driving signal line SS corresponding to the string selection line SSL. The gate pass transistor TRg may be configured to connect the ground selection line GSL to the ground selection line-driving signal line GS corresponding to the ground selection line GSL. For example, when the block selection signal is activated, the plurality of pass transistors TRs, TR1 to TRm, and TRg may provide driving signals, which may be respectively provided through the string selection line-driving signal line SS, the first to m-th word line-driving signal lines SI1 to SIm, and the ground selection line-driving signal lines GS, to the string selection line SSL, the plurality of word lines WL1 to WLm, and the ground selection line GSL.

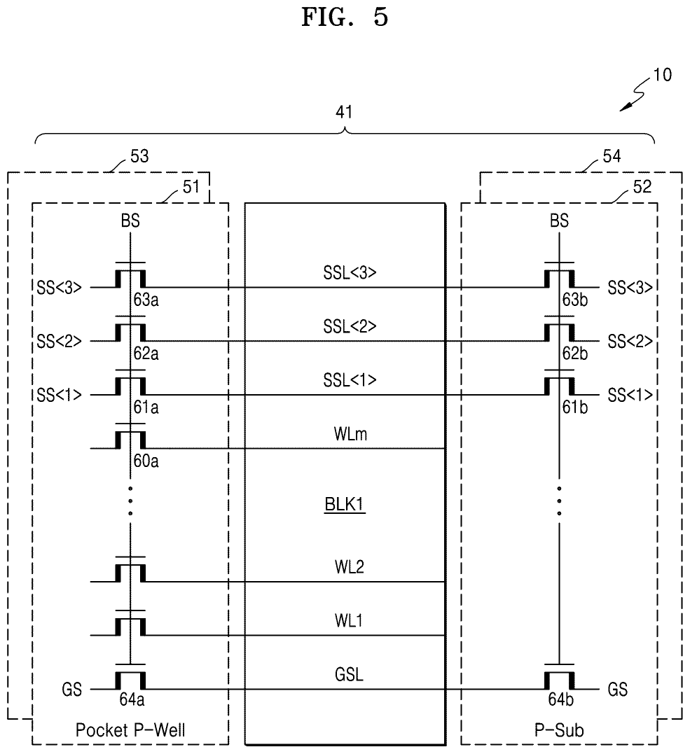

FIG. 5 is a diagram for describing the memory device 10 including a pass transistor circuit 41, according to embodiments. FIG. 5 describes the pass transistor circuit 41 in conjunction with the memory block BLK1 illustrated in FIG. 3.

Referring to FIG. 5, in the memory device 10, the pass transistor circuit 41 of the memory block BLK1 may include a first pass transistor circuit 51 and a second pass transistor circuit 52. The first pass transistor circuit 51 may be on left of the memory block BLK1, and the second pass transistor circuit 52 may be on right of the memory block BLK1. However, the present disclosure is not limited in this regard. The first pass transistor circuit 51 may be configured to be substantially similar to and/or the same (e.g., identical) as the pass transistor circuit 40 described with reference to FIG. 4.

In an embodiment, the first pass transistor circuit 51 may be configured such that voltage levels of the first to m-th word line-driving signal lines SI1 to SIm are provided to the plurality of word lines WL1 to WLm of the memory block BLK1 through a pass transistor 60a. In addition, the first string selection line SSL<1>, the second string selection line SS<2>, and the third string selection line SSL<3> may be respectively connected to the string selection line-driving signal lines (e.g., a first string selection line-driving signal line SS<1>, a second string selection line-driving signal line SS<2>, and a third string selection line-driving signal line SS<3>) corresponding thereto. The second pass transistor circuit 52 may be different from the first pass transistor 51 in that pass transistors configured to provide the voltage levels of the first to m-th word line-driving signal lines SI1 to SIm to the plurality of word lines WL1 to WLm of the memory block BLK1 may not be included in the second pass transistor circuit 52.

A voltage level of the first string selection line-driving signal line SS<1> may be provided to the first string selection line SSL<1> through first pass transistors 61a and 61b at both ends of the first string selection line SSL<1>. A voltage level of the second string selection line-driving signal line SS<2> may be provided to the second string selection line SSL<2> by second pass transistors 62a and 62b at both ends of the second string selection line SSL<2>. A voltage line of the third string selection line-driving signal line SS<3> may be provided to the third string selection line SSL<3> by third pass transistors 63a and 63b at both ends of the third string selection line SSL<3>. A voltage level of the ground selection line-driving signal line GS may be provided to the ground selection line GSL through fourth pass transistors 64a and 64b at both ends of the ground selection line GSL.

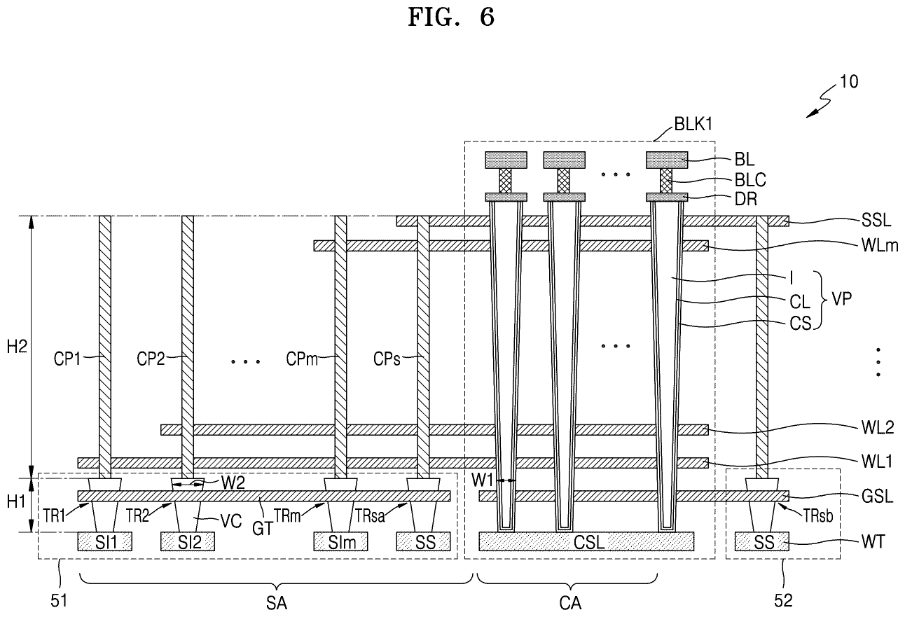

In a cell string structure that is 3D formed, the string selection lines SSL<1>, SSL<2>, and SSL<3> and the ground selection line GSL may have a resistance R1 and a capacity C1 that may be relatively greater than a resistance R2 and a capacity C2 of the plurality of word lines WL1 to WLm. For example, as illustrated in FIG. 6, as a pillar diameter of a vertical channel structure VP increases, an effective area of a conductive layer forming the plurality of word lines WL1 to WLm decreases, and consequently, a resistance increases. In addition, the capacity formed between each film layer also increases. Accordingly, as a diameter of the pillar increases, a coupling capacity and a resistance of the cell transistor increases. In such a manner, a resistance and a capacity of the string selection transistor SST at an uppermost layer of the pillar may have greatest (e.g., larger) values than resistance and capacity values of lower layers. As a result, an increase in a time constant of the string selection line SSL and decrease a setup speed of the string selection signal may be observed. That is, due to the resistance R and the capacity C having relatively large values, a speed at which the voltage level of the string selection line-driving signal lines SS<1>, SS<2>, and SS<3> may be set up to the string selection lines SSL<1>, SSL<2>, and SSL<3> may decrease. To potentially reduce the decrease in the setup speed, the string selection lines SSL<1>, SSL<2>, and SSL<3> and the ground selection line GSL may be double-driven in both directions.

Returning to FIG. 5, in some embodiments, the pass transistor 41 of the memory block BLK1 may further include a third pass transistor circuit 53 and a fourth pass transistor circuit 54 configured to be substantially similar to and/or the same (e.g., identical) as the second pass transistor circuit 52. The third pass transistor circuit 53 may be in front of the memory block BLK1, and the second pass transistor circuit 52 may be behind the memory block BLK1. In such a manner, the speed at which the voltage level of the string selection line-driving signal lines SS<1>, SS<2>, and SS<3> may be set up to the string selection lines SSL<1>, SSL<2>, and SSL<3> may increase.

In some embodiments, pass transistors of the first pass transistor circuit 51 may be formed in a pocket P-type well area, and pass transistors of the second pass transistor circuit 52 may be formed on a P-type substrate. The pass transistors may be configured to drive at a negative voltage level during operations of the memory device 10. For example, in a read operation, a negative voltage may be provided to a source area of a pass transistor, which may be connected to a selected word line, from among the first to m-th pass transistors TR1 to TRm configured to drive the plurality of word lines WL1 to WLm. Accordingly, the first to m-th pass transistors TR1 to TRm configured to drive the plurality of word lines WL1 to WLm may need to be formed in the pocket P-type well area well-biased with the negative voltage.

In some embodiments, the first to fourth pass transistors 61a to 64a and 61b to 64b configured to drive the string selection lines SSL<1>, SSL<2>, and SSL<3> and the ground selection line GSL may use a voltage level that is not lower than a level of the ground voltage GND to drive the operations (e.g., read operations, program operations, erase operations, or the like) of the memory device 10, and may not use a negative voltage for driving the operations. Therefore, pass transistors of the second pass transistor circuit 52 in which the first to m-th pass transistors TR1 to TRm configured to drive the word lines WL1 to WLm are not formed may be formed on a P-type substrate biased with the ground voltage GND. Hereinafter, the memory devices in which the pass transistor circuits are formed are described with reference to FIGS. 6 to 8.

FIG. 6 is a cross-sectional view schematically illustrating the memory device including the pass transistor 41 illustrated in FIG. 5, according to embodiments. The cross-sectional view shown in FIG. 6 is a combination of one or more cut surfaces. For convenience of explanation, terms described as top surface/bottom surface, top/bottom, on/above, left/right are used with reference to directions shown in the drawings. Therefore, even a same surface may be referred to as a top surface and a lower surface according to the directions shown in the drawings.

Referring to FIG. 6, the memory device 10 may include the memory block BLK1, a plurality of pass transistors TR1 to TRm, TRsa, and TRsb, and the plurality of driving signal lines SI1 to SIm and SS. For example, the memory device 10 may correspond to a portion of the cell array structure CAS shown in FIG. 2, and a page buffer, a control logic, or the like may be arranged under the memory block BLK1, the plurality of pass transistors TR1 to TRm and TRs, and the plurality of driving signal lines SI1 to SIm and SS in a vertical direction VD, that is, in the peripheral circuit structure PCS.

The memory block BLK1 may be arranged in a cell area CA and may include the plurality of word lines WL1 to WLm. The plurality of word lines WL1 to WLm may be stacked in the vertical direction D and may extend in the first horizontal direction HD1. In an embodiment, the plurality of word lines WL1 to WLm may be electrically insulated through a plurality of insulating films. Ends of the plurality of word lines WL1 to WLm in the first horizontal direction HD1 may be implemented in a stair shape, and the stair shape may be referred to as a stair area SA.

The memory block BLK1 may further include the common source line CSL arranged under the plurality of word lines WL1 to WLm. In an embodiment, the common source line CSL and the plurality of driving signal lines SI1 to SIm and SS may be arranged at a same level. In an embodiment, the common source line CSL and the plurality of driving signal lines (e.g., the word line-driving signal lines SI1 to SIm and string selection line-driving signal lines SS) may be implemented as a metal layer MT. For example, the common source line CSL may be implemented as a metal plate of the metal layer MT and/or a conductive plane.

The memory block BLK1 may further include the vertical channel structure VP. The vertical channel structure VP may extend in the vertical direction VD and penetrate through the plurality of word lines WL1 to WLm and the plurality of insulating films. The vertical channel structure VP may also be referred to as a pillar. The vertical channel structure VP may have a first width W1 in the first horizontal direction HD1. For example, a plurality of the vertical channel structures VP may be formed in an annular shape. In such a case, the first width W1 may correspond to a size of a first channel hole. However, the present disclosure is not limited thereto, and, for example, the vertical channel structure VP may also be formed in an elliptical pillar or a square pillar. The plurality of vertical channel structures VP may be arranged apart from one another in the first horizontal direction HD1 and a second horizontal direction HD2.

The vertical channel structure VP may include a charge storage layer CS, a channel layer CL, and an internal layer I. The channel layer CL may include a silicon (Si) material having a first conductive type (e.g., P-type), and may function as a channel area. The internal layer I may include an insulating material, such as, but not limited to, silicon oxide (SiO₂), an air gap, or the like. The charge storage layer CS may include a gate insulating layer (that may also be referred to as a tunneling insulating layer), a charge trap layer, and a blocking insulating layer. For example, the charge storage layer CS may have an oxide-nitride-oxide (ONO) structure.

Drains or drain contacts DR may be respectively provided on the plurality of vertical channel structures VP. For example, the drains or the drain contacts DR may include a silicon (Si) material doped with impurities having a second conductive type (e.g., N type). Bit lines BL may be provided above the drain contacts DR, and the bit lines BL may be respectively connected to the drain contacts DR through bit line contacts BLC.

The memory block BLK1 may further include the ground selection line GSL, which may be between the plurality of word lines WL1 to WLm and the common source line CSL, and the string selection line SSL arranged above the plurality of word lines WL1 to WLm. Although FIG. 6 illustrates that the memory device 10 includes only one string selection line SSL, the present disclosure is not limited thereto, and the memory device 10 may include the plurality of string selection lines SSL<1>, SSL<2>, and SSL<3>, as illustrated in FIG. 5.

The plurality of pass transistors TR1 to TRm, TRsa, and TRsb may be arranged in the stair area SA of the plurality of word lines WL1 to WLm. Each of the plurality of pass transistors TR1 to TRm may be connected between a corresponding word line and a corresponding driving signal line. For example, a first pass transistor TR1 may be connected between the first word line WL1 and the first word line-driving signal line SI1, a second pass transistor TR2 may be connected between the second word line WL2 and the second word line-driving signal line SI2, and an m-th pass transistor TRm may be connected between an m-th word line WLm and an m-th word line-driving signal line SIm. The pass transistors TRsa and TRsb may be connected between the string selection line SSL and the string selection line-driving signal line SS.

Each of the plurality of pass transistors TR1 to TRm, TRsa, and TRsb may include a vertical channel VC extending in the vertical direction VD. The vertical channel VC may have a second width W2 greater than the first width W1, and accordingly, issues of breakdown of the pass transistors TR1 to TRm and TRs may potentially be resolved. For example, the second width W2 may be about at least twice the first width W1. However, the present disclosure is not limited in this regard, and the first width W1 and the second width W2 may be variously modified according to embodiments. A height in the vertical direction VD of the plurality of vertical channels VC may be substantially similar and/or the same (e.g., identical) (e.g., a first height H1). A level of top surfaces of the plurality of vertical channels VC may be lower than a level of a bottom surface of the first word line WL1.

In some embodiments, the vertical channel VC and the vertical channel structure VP may be formed in a same structure through a same process. Accordingly, the vertical channel VC also may include the charge storage layer CS, the channel layer CL, and the internal layer I. However, the present disclosure is not limited thereto, and in some embodiments, the vertical channel VC may only include the channel layer CL and the internal layer I.

The vertical channels VC respectively included in the plurality of pass transistors TR1 to TRm, TRsa, and TRsb may be connected in common to a gate GT. The gate GT may be connected to the block selection signal BS line (see FIG. 5). In an embodiment, the gate GT connected in common to the plurality of pass transistors TR1 to TRm, TRsa, and TRsb may be arranged at a same level as a level of the ground selection line GSL. In some embodiments, vertical channels VC included in the plurality of pass transistors TR1 to TRm, TRsa, and TRsb may be respectively connected to different gates GT, the different gates GT may have different lengths in the vertical direction VD, and accordingly, the pass transistors TR1 to TRm, TRsa, and TRsb may respectively have different driving performances.

In some embodiments, the length in the vertical direction VD of the gate GT may be variously determined. The length in the vertical direction VD of the gate GT may be substantially similar to and/or the same (e.g., identical) as a length in the vertical direction VD of the ground selection line GSL. The length of the gate GT in the vertical direction VD may be substantially similar to and/or the same (e.g., identical) as a length in the vertical direction VD of each of the word lines WL1 to WLm. Alternatively, the length in the vertical direction VD of the gate GT may be substantially similar to and/or the same (e.g., identical) as to a length in the vertical direction VD of the string selection line SSL. However, these are non-limiting examples for descriptions, and the present disclosure is not limited thereto.

A plurality of contacts CP1 to CPm, CPsa, and CPsb may be respectively arranged on the plurality of pass transistors TR1 to TRm, TRsa, and TRsb. The plurality of pass transistors TR1 to TRm may be respectively connected to corresponding word lines WL1 to WLm through corresponding contacts CP1 to CPm, and each of the pass transistors TRsa and TRsb may be connected to the string selection line SSL through corresponding contacts CPsa and CPsb. The plurality of contacts CP1 to CPm, CPsa, and CPsb in the vertical direction VD may have a same height (e.g., a second height H2). For example, a level of top surfaces of the plurality of contacts CP1 to CPm, CPsa, and CPsb may be substantially similar to and/or the same (e.g., identical) as a level of a top surface of the string selection line SSL.

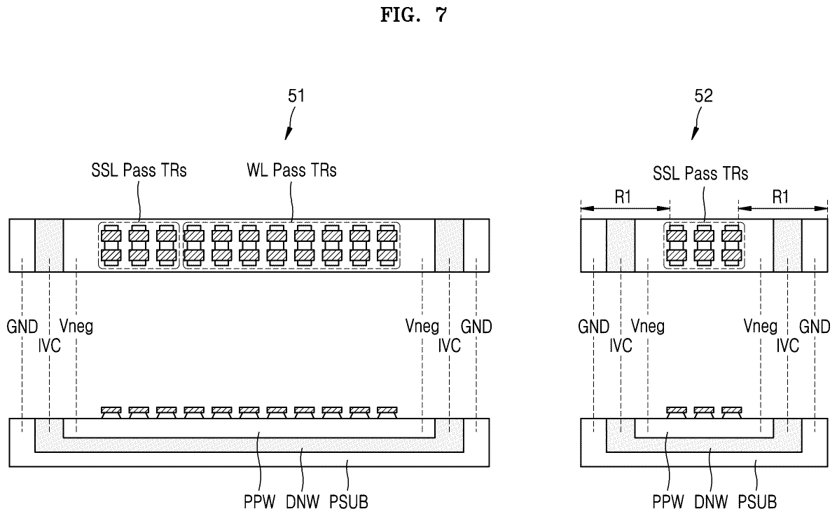

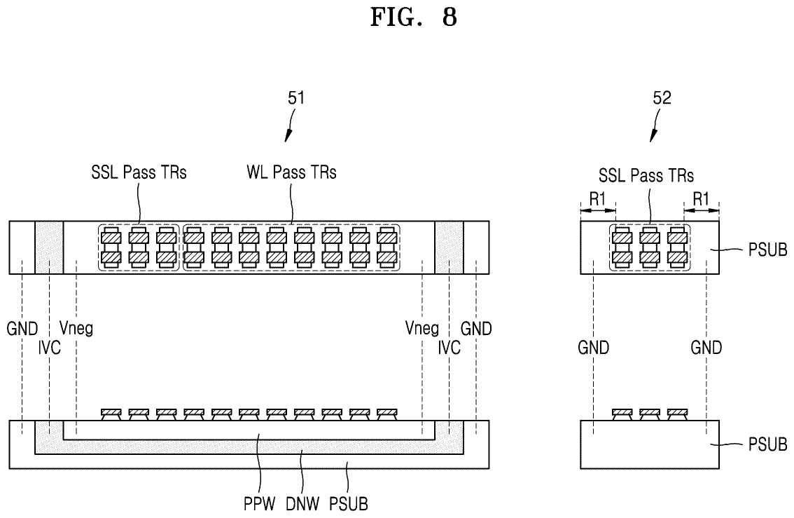

FIGS. 7 and 8 are diagrams for describing areas occupied by the pass transistor circuits 51 and 52 illustrated in FIG. 5. FIG. 7 illustrates a top-plan view and a cross-sectional view in which the first pass transistor circuit 51 and the second pass transistor circuit 52 illustrated in FIG. 5 are formed in a pocket P-type well PPW. FIG. 8 illustrates a top-plan view and a cross-sectional view in which the first pass transistor circuit 51 is formed in the pocket P-type well PPW and the second pass transistor circuit 52 is formed on the P-type substrate.

FIG. 7 illustrates that the pass transistors of the first pass transistor circuit 51 and the second pass transistor circuit 52 are formed in the pocket P-type well PPW formed in a deep N-type well DNW formed on a P-type substrate PSUB. It is seen that that the P-type substrate PSB is biased with the ground voltage GND, the deep N-type well DNW is biased with an internal power voltage IVC having a positive voltage level, and the pocket P-type well PPW is biased with the negative voltage Vneg. In the second pass transistor circuit 52, the pass transistors configured to drive the string selection lines SSL<1>, SSL<2>, and SSL<3> may need to be arranged while maintaining a first interval R1 including a minimum width of the P-type substrate PSUB, a minimum width of the deep N-type well DNW, and a minimum width of the pocket P-type well PPW regulated for semiconductor processes.

FIG. 8 illustrates that the pass transistors of the first pass transistor circuit 51 is formed in the pocket P-type well PPW formed in the deep N-type well DNW formed on the P-type substrate PSUB and the second pass transistor circuit 52 is formed on the P-type substrate. In the second pass transistor circuit 52, the pass transistors configured to drive the string selection lines SSL<1>, SSL<2>, SSL<3> may need to be arranged with a second interval R2 including the minimum width of the P-type substrate PSUB regulated for semiconductor processes. As the second interval R2 is less than the first interval R1 illustrated in FIG. 7, the chip size may be reduced, when compared to related memory devices.

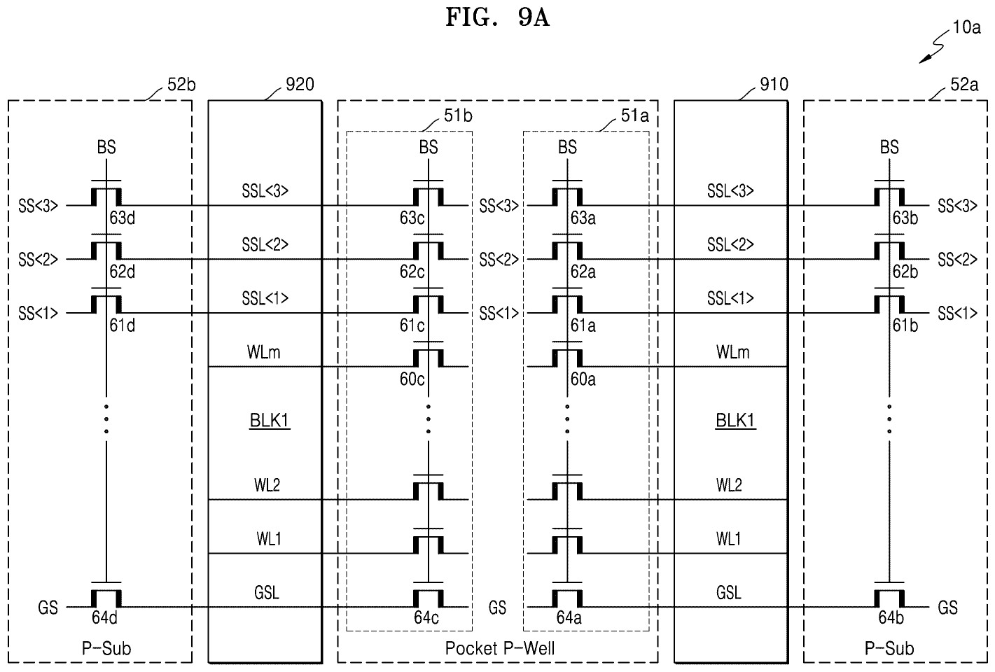

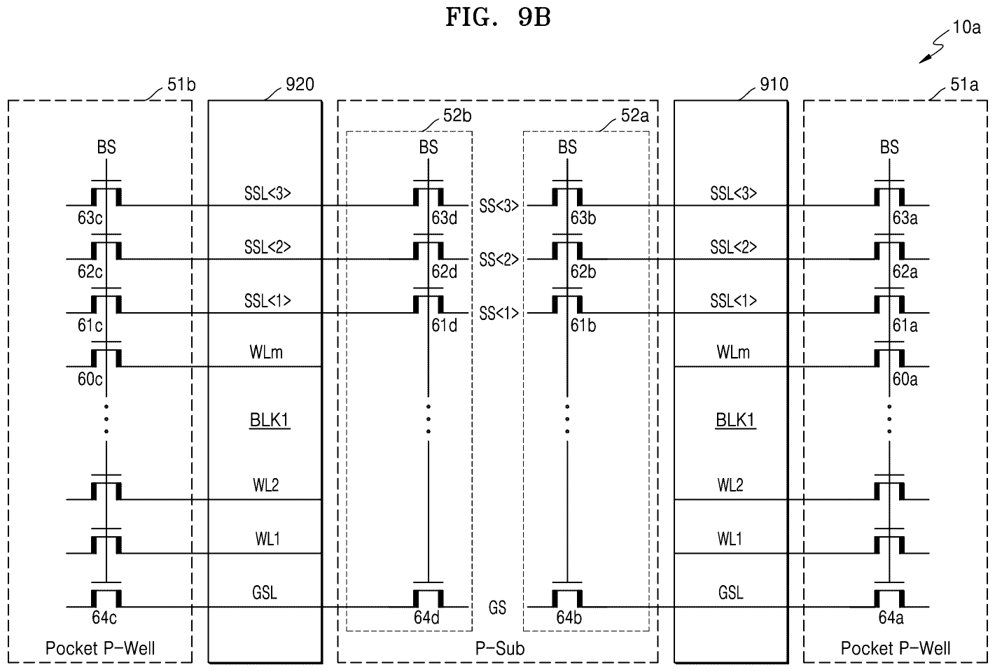

FIGS. 9A and 9B are diagrams for describing a memory device 10a including pass transistors circuits, according to embodiments. Hereinafter, subscripts added to a same reference number (e.g., a of 10a, b of 10b) in different drawings are used to distinguish a plurality of components having similar functions or a same function. For the sake of brevity, redundant descriptions as those of the memory device 10 illustrated in FIG. 6 may not be given for the memory device 10a.

FIGS. 9A and 9B illustrate a structure of the memory device 10a, in which the memory block BLK1 is divided into two sub blocks 910 and 920 in a first direction. The word lines WL1 to WLm in the first sub block 910 may be driven by a pass transistor 60a of the first pass transistor circuit 51a, and the word lines WL1 to WLm in the second sub block 920 may be driven by a pass transistor 60c of the first pass transistor circuit 51b. The string selection lines SSL<1>, SSL<2>, and SSL<3> and a ground selection line GSL in the first sub block 910 may be driven by pass transistors 61a, 62a, 63a, and 64a of the first pass transistor circuit 51a and pass transistors 61b, 62b, 63b, and 64b of the second pass transistor circuit 52a. The string selection lines SSL<1>, SSL<2>, and SSL<3> and a ground selection line GSL in the second sub block 920 may be driven by pass transistors 61c, 62c, 63c, and 64c of the first pass transistor circuit 51b and pass transistors 61d, 62d, 63d, and 64d of the second pass transistor circuit 52b.

In FIG. 9A, the first pass transistor circuits 51a and 51b may be arranged between the first sub block 910 and the second sub block 920, and the second pass transistor circuits 52a and 52b may be arranged in edges in the first direction of the first sub block 910 and the second sub block 920. Although FIG. 9A illustrates an example in which two first pass transistor circuits 51a and 51b drive the string selection lines SSL<1>, SSL<2>, and SSL<3>, the ground selection line GSL and the word lines WL1 to WLm in each of the first sub block 910 and the second sub block 920, the string selection lines SSL<1>, SSL<2>, SSL<3>, the ground selection line GSL, and the word lines WL1 to WLm in each of the first sub block 910 and the second sub block 920 may be driven by using one first pass sub transistor 51a or 51b.

In FIG. 9B, the second pass transistor circuits 52a and 52b may be arranged between the first sub block 910 and the second sub block 920, and the first pass transistor circuits 51a and 51b may be arranged at edges of the first sub block 910 and the second sub block 920 in the first direction. Although FIG. 9B illustrates an example in which two second pass transistor circuits 52a and 52b drive the string selection lines SSL<1>, SSL<2>, and SSL<3> and the ground selection line GSL in each of the first sub block 910 and the second sub block 920, the string selection lines SSL<1>, SSL<2>, and SSL<3> and the ground selection line GSL may be driven by using one second pass transistor circuit 910 52a or 52b.

The string selection lines SSL<1>, SSL<2>, and SSL<3> and the ground selection line GSL in the first sub block 910 may be double-driven in two directions by the pass transistors 61a to 64a included in the first pass transistor circuit 51a and the pass transistors 61b to 64b included in the second pass transistor circuit 52a, and the string selection lines SSL<1>, SSL<2>, and SSL<3> and the ground selection line GSL in the second sub block 920 may be double-driven in two directions by the pass transistors 61c to 64c included in the first pass transistor circuit 51c and the pass transistors 61d to 64d included in the second pass transistor circuit 52d. The first pass transistor circuits 51a and 51b may be formed in the pocket P-type well PPW, and the second pass transistor circuits 52a and 52b may be formed on the P-type substrate.

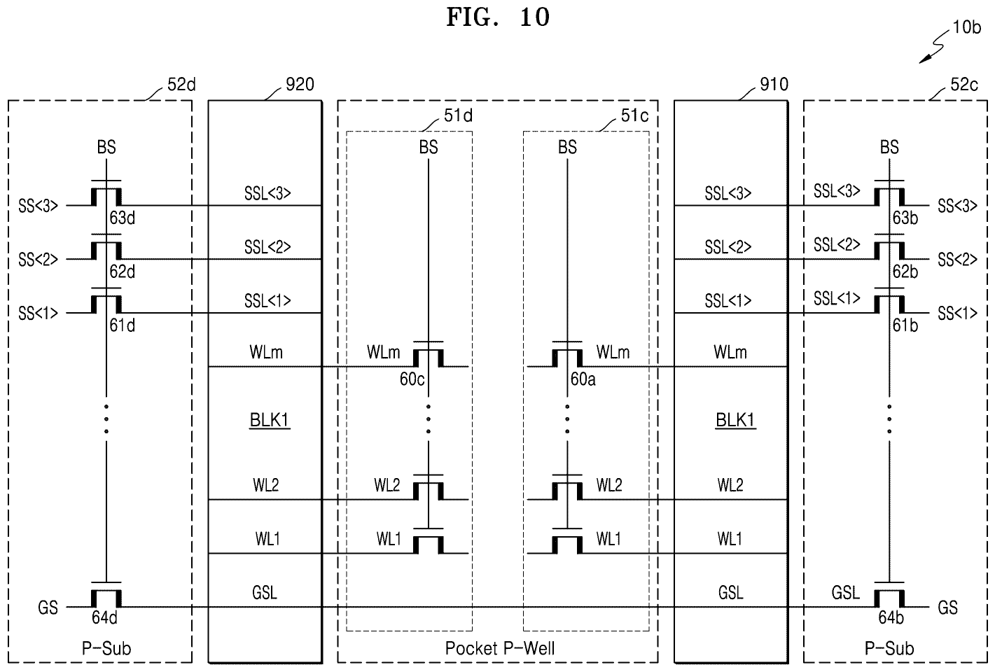

FIG. 10 is a diagram for describing a memory device 10b including pass transistors 51c, 51d, 52c, and 52d, according to embodiments. For the sake of brevity, redundant descriptions as those of the memory device 10a illustrated in FIGS. 9A and 9B may not be given for the memory device 10b.

Referring to FIG. 10, compared with the memory device 10a, a difference in the memory device 10b may be that the first pass transistor circuit 51c does not include pass transistors configured to drive the string selection lines SSL<1>, SSL<2>, and SSL<3> and the ground selection line GSL in the first sub block 910 and the first pass transistor circuit 51d does not include pass transistors configured to drive the string selection lines SSL<1>, SSL<2>, and SSL<3> and the ground selection line GSL in the second sub block 920. The string selection lines SSL<1>, SSL<2>, and SSL<3>, and the ground selection line GSL in the first sub block 910 may be driven by the pass transistors 61b to 64b of the second pass transistor circuit 52a. The string selection lines SSL<1>, SSL<2>, and SSL<3> and the ground selection line GSL in the second sub block 920 may be driven by the pass transistors 61d to 64d of the second pass transistor circuit 52b. The first pass transistor circuits 51c and 51d may be formed in the pocket P-type well, and the second pass transistor circuits 52a and 52b may be formed on the P-type substrate.

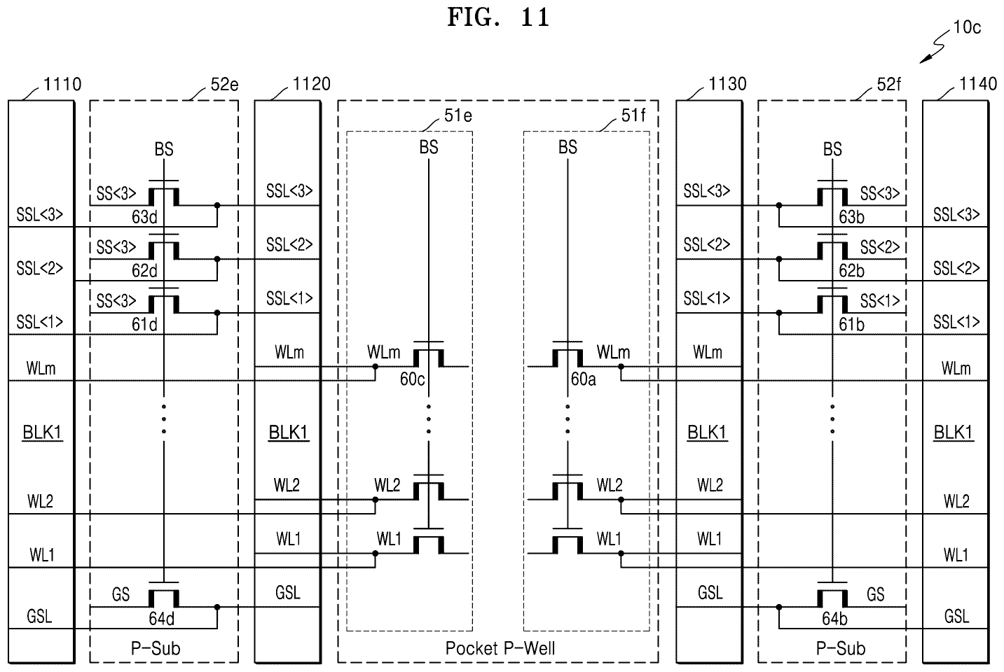

FIG. 11 is a diagram for describing a memory device 10c including pass transistors 51e, 51f, 52c, and 52f, according to embodiments. For the sake of brevity, redundant descriptions as those of the memory device 10b illustrated in FIG. 10 may not be given for the memory device 10c.

FIG. 11 illustrates a structure of the memory device 10c, in which a memory block BLK1 is split into four sub blocks 1110, 1120, 1130, and 1140. The word lines WL1 to WLm of the first sub block 1110 and the second sub block 1120 may be driven by a pass transistor 60c of the first pass transistor circuit 51e, and the word lines WL1 to WLm in the third sub block 1130 and the fourth sub block 1140 may be driven by a pass transistor 60a of a first pass transistor 51f.

The string selection lines SSL<1>, SSL<2>, and SSL<3> and the ground selection line GSL in the first sub block 1110 and the second sub block 1120 may be driven by pass transistors 61d to 64d of the second pass transistor circuit 52e. The string selection lines SSL<1>, SSL<2>, and SSL<3> and the ground selection line GSL in the third sub block 1130 and the fourth sub block 1140 may be driven by the pass transistors 61b to 64b of the second pass transistor circuit 52f. The first pass transistor circuits 51e and 51f may be formed in the pocket P-type well, and the second pass transistor circuits 52e and 52f may be formed on the P-type substrate.

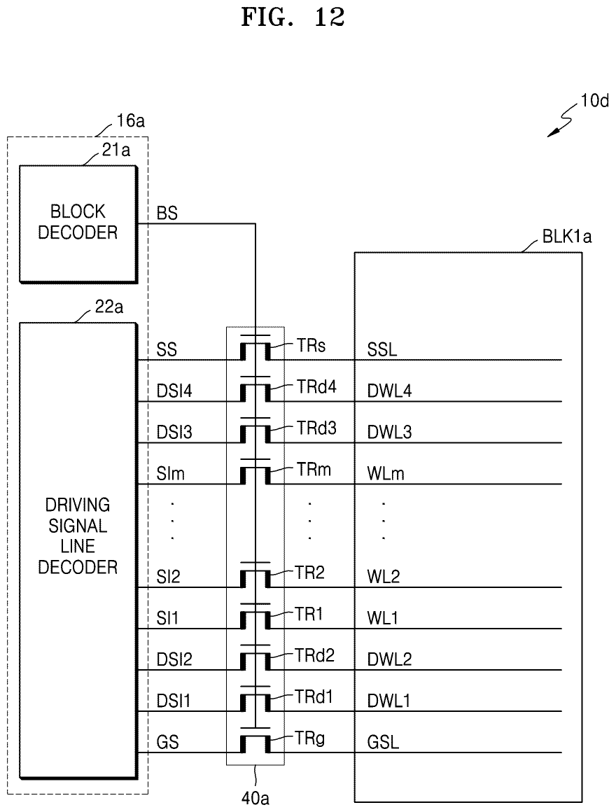

FIG. 12 is a diagram for describing a memory device 10d including a row decoder 16a and a pass transistor circuit 40a, according to embodiments.

Referring to FIG. 12, in the memory device 10d, compared with the memory block BLK1 illustrated in FIG. 4, a memory block BLK1a may further include a first dummy word line DWL1 to a fourth dummy word line DWL4. The first dummy word line DWL1 and the second dummy word line DWL2 may be arranged between the ground selection line GSL and the first word line WL1, and the third dummy word line DWL3 and the fourth dummy word line DWL4 may be arranged between the m-th word line WLm and the string selection line SSL. In some embodiments, the memory block BLK1a may include at least one of the first dummy word line DWL1 to the fourth dummy word line DWL4. According to embodiments, the number of dummy word lines included in the memory block BLK1a may be variously modified.

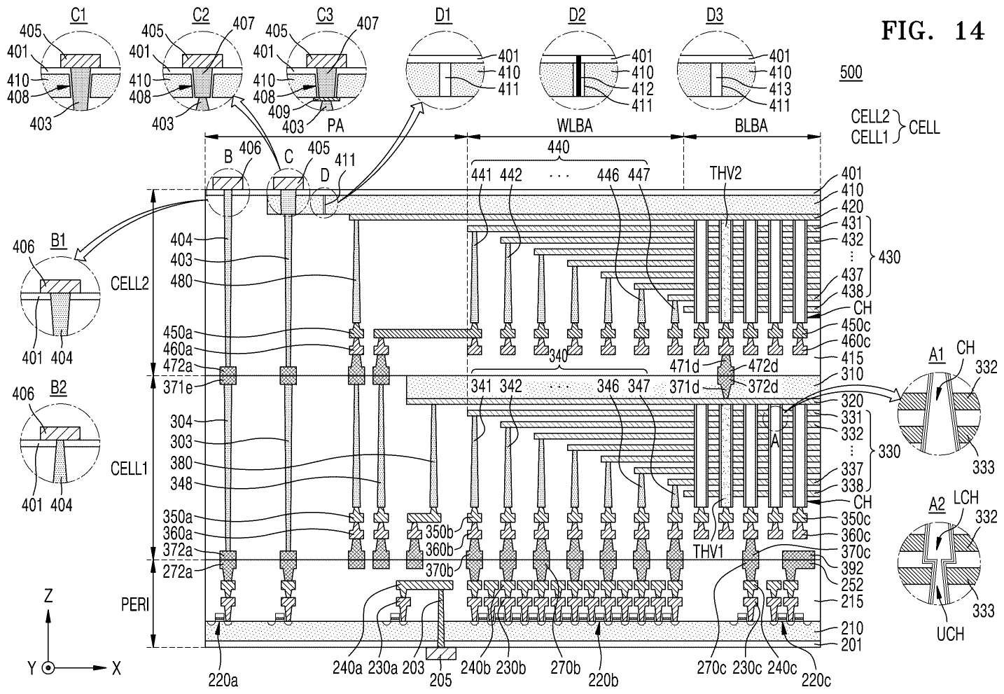

In some embodiments, regarding the dummy word lines included in the memory block BLK1a, when a channel structure CH is formed to include a lower channel LCH and an upper channel UCH, a word line near a boundary between the lower channel LCH and the upper channel UCH may include the dummy word line, as illustrated in A2 of FIG. 14. For example, the word line 332 and the word line 333 forming the boundary between the lower channel LCH and the upper channel UCH may include dummy word lines.

The row decoder 16a may correspond to an example of modification of the row decoder 16 illustrated in FIG. 4, and the pass transistor circuit 40a may correspond to an example of modification of the pass transistor circuit 40 illustrated in FIG. 4. Compared with the pass transistor circuit 40 illustrated in FIG. 4, the pass transistor circuit 40a may further include pass transistors TRd1 to TRd4. The pass transistors TRd1 to TRd4 may connect the first to fourth dummy word lines DWL1 to DWL4 respectively to corresponding dummy word line-driving signal lines DSI1 to DSI4.

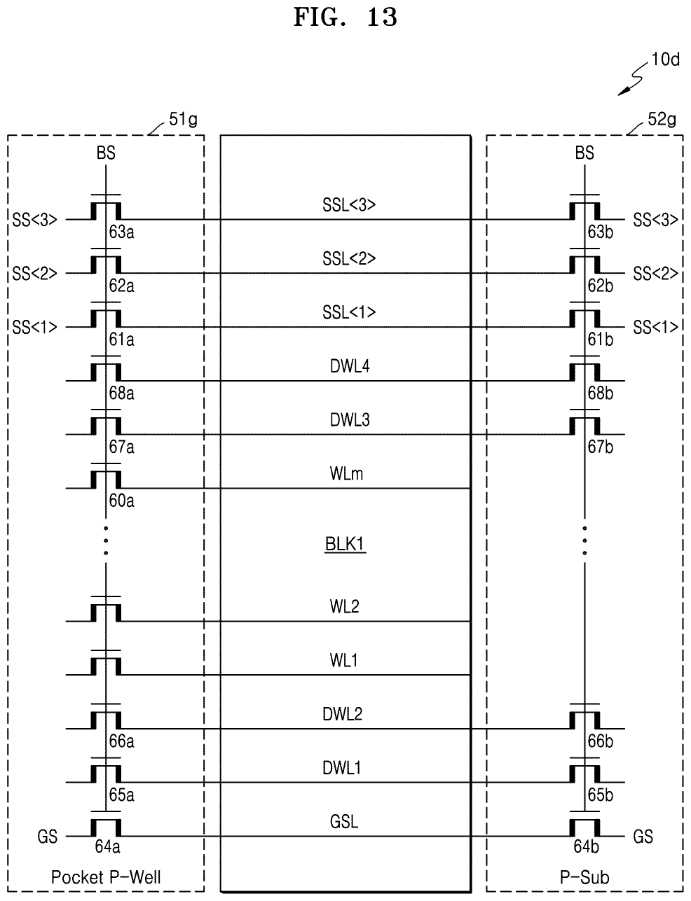

FIG. 13 is a diagram for describing the memory device 10d including the pass transistor circuits illustrated in FIG. 12. For the sake of brevity, redundant descriptions as those of the memory device 10 illustrated in FIG. 5 may not be given for the memory device 10d.

Referring to FIG. 13, compared with the memory device 10, in the memory device 10d, the first dummy word line DWL1 to the fourth dummy word line DWL4 may be double-driven in two directions by pass transistors 65a to 68a of a first pass transistor circuit 51g and pass transistors 65b to 68b of a second pass transistor circuit 52g. The first pass transistor circuit 51g may be formed in the pocket P-type well, and the second pass transistor circuit 52g may be formed on the P-type substrate.

FIG. 14 is a view illustrating a memory device 500, according to some embodiments of the present disclosure.

Referring to FIG. 14, the memory device 500 may have a chip-to-chip (C2C) structure. At least one upper chip including a cell region and a lower chip including a peripheral circuit region PERI may be manufactured separately, and then, the at least one upper chip and the lower chip may be connected to each other by a bonding method to realize the C2C structure. For example, the bonding method may refer to a method of electrically and/or physically connecting a bonding metal pattern formed in an uppermost metal layer of the upper chip to a bonding metal pattern formed in an uppermost metal layer of the lower chip. For example, in a case in which the bonding metal patterns are formed of copper (Cu), the bonding method may be referred to as a Cu—Cu bonding method. Alternatively, the bonding metal patterns may be formed of aluminum (Al), tungsten (W), or the like.

The memory device 500 may include the at least one upper chip including the cell region. For example, as illustrated in FIG. 14, the memory device 500 may include two (2) upper chips. However, the number of the upper chips is not limited thereto. In the case in which the memory device 500 includes the two (2) upper chips, a first upper chip including a first cell region CELL1, a second upper chip including a second cell region CELL2 and the lower chip including the peripheral circuit region PERI may be manufactured separately, and then, the first upper chip, the second upper chip and the lower chip may be connected to each other by the bonding method to manufacture the memory device 500. The first upper chip may be turned over and then may be connected to the lower chip by the bonding method, and the second upper chip may also be turned over and then may be connected to the first upper chip by the bonding method. Hereinafter, upper and lower portions of each of the first and second upper chips are be defined based on the orientation of the chips before each of the first and second upper chips is turned over. In other words, an upper portion of the lower chip may refer to an upper portion defined based on a +Z-axis direction, and the upper portion of each of the first and second upper chips may refer an upper portion defined based on a −Z-axis direction in FIG. 14. However, embodiments of the present disclosure are not limited thereto. In certain embodiments, one of the first upper chip and the second upper chip may be turned over and then may be connected to a corresponding chip by the bonding method.

Each of the peripheral circuit region PERI and the first and second cell regions CELL1 and CELL2 of the memory device 500 may include an external pad bonding region PA, a word line bonding region WLBA, and a bit line bonding region BLBA.

The peripheral circuit region PERI may include a first substrate 210 and a plurality of circuit elements (e.g., 220a, 220b and 220c) formed on the first substrate 210. An interlayer insulating layer 215 including one or more insulating layers may be provided on the plurality of circuit elements 220a to 220c, and a plurality of metal lines electrically connected to the plurality of circuit elements 220a to 220c may be provided in the interlayer insulating layer 215. For example, the plurality of metal lines may include first metal lines (e.g., 230a, 230b and 230c) connected to the plurality of circuit elements 220a to 220c, and second metal lines (e.g., 240a, 240b and 240c) formed on the first metal lines 230a to 230c. The plurality of metal lines may be formed of at least one of various conductive materials. For example, the first metal lines 230a to 230c may be formed of tungsten (W) having a relatively high electrical resistivity, and the second metal lines 240a to 240c may be formed of copper having a relatively low electrical resistivity.

The first metal lines 230a to 230c and the second metal lines 240a to 240c are illustrated and described in the present embodiments. However, embodiments of the present disclosure are not limited thereto. In certain embodiments, at least one or more additional metal lines may further be formed on the second metal lines 240a to 240c. In such a case, the second metal lines 240a to 240c may be formed of aluminum (Al), and at least some of the additional metal lines formed on the second metal lines 240a to 240c may be formed of copper (Cu) having an electrical resistivity lower than that of aluminum (Al) of the second metal lines 240a to 240c.

The interlayer insulating layer 215 may be disposed on the first substrate 210 and may include an insulating material such as silicon oxide (SiO₂) and/or silicon nitride (Si₃N₄).

Each of the first and second cell regions CELL1 and CELL2 may include at least one memory block. The first cell region CELL1 may include a second substrate 310 and a common source line 320. A plurality of word lines 330 (e.g., a first word line 331, a second word line 332, a third word line 333, a fourth word line 334, a fifth word line 335, a sixth word line, a seventh word line 337, and an eighth word line 338) may be stacked on the second substrate 310 in a direction (e.g., the Z-axis direction) perpendicular to a top surface of the second substrate 310. String selection lines and a ground selection line may be disposed on and under the plurality of word lines 330, and the plurality of word lines 330 may be disposed between the string selection lines and the ground selection line. Likewise, the second cell region CELL2 may include a third substrate 410 and a common source line 420, and a plurality of word lines 430 (e.g., a first word line 431, a second word line 432, a third word line 433, a fourth word line 434, a fifth word line 435, a sixth word line 436, a seventh word line 437, and an eighth word line 438) may be stacked on the third substrate 410 in a direction (e.g., the Z-axis direction) perpendicular to a top surface of the third substrate 410. Each of the second substrate 310 and the third substrate 410 may be formed of at least one of various materials and may be, for example, a silicon (Si) substrate, a silicon-germanium (Si—Ge) substrate, a germanium (Ge) substrate, or a substrate having a single-crystalline epitaxial layer grown on a single-crystalline silicon (Si) substrate. A plurality of channel structures CH may be formed in each of the first and second cell regions CELL1 and CELL2.

In some embodiments, as illustrated in a region A1, the channel structure CH may be provided in the bit line bonding region BLBA and may extend in the direction perpendicular to the top surface of the second substrate 310 to penetrate the word lines 330, the string selection lines, and the ground selection line. The channel structure CH may include a data storage layer, a channel layer, and a filling insulation layer. The channel layer may be electrically connected to a first metal line 350c and a second metal line 360c in the bit line bonding region BLBA. For example, the second metal line 360c may be a bit line and may be connected to the channel structure CH through the first metal line 350c. The bit line 360c may extend in a first direction (e.g., a Y-axis direction) parallel to the top surface of the second substrate 310.

In some embodiments, as illustrated in a region A2, the channel structure CH may include a lower channel LCH and an upper channel UCH, which are connected to each other. For example, the channel structure CH may be formed by a process of forming the lower channel LCH and a process of forming the upper channel UCH. The lower channel LCH may extend in the direction perpendicular to the top surface of the second substrate 310 to penetrate the common source line 320 and lower word lines 331 and 332. The lower channel LCH may include a data storage layer, a channel layer, and a filling insulation layer and may be connected to the upper channel UCH. The upper channel UCH may penetrate upper word lines (e.g., the third word line 333 to the eighth word line 338). The upper channel UCH may include a data storage layer, a channel layer, and a filling insulation layer, and the channel layer of the upper channel UCH may be electrically connected to the first metal line 350c and the second metal line 360c. As a length of a channel increases, due to characteristics of manufacturing processes, it may be difficult to form a channel having a substantially uniform width. The memory device 500, according to the present embodiments, may include a channel having improved width uniformity due to the lower channel LCH and the upper channel UCH which are formed by the processes performed sequentially.

In the case in which the channel structure CH includes the lower channel LCH and the upper channel UCH as illustrated in the region A2, a word line located near to a boundary between the lower channel LCH and the upper channel UCH may be a dummy word line. For example, the second and third word lines 332 and 333 adjacent to the boundary between the lower channel LCH and the upper channel UCH may be the dummy word lines. In such a case, data may not be stored in memory cells connected to the dummy word line. Alternatively, the number of pages corresponding to the memory cells connected to the dummy word line may be less than the number of pages corresponding to the memory cells connected to a general word line. A level of a voltage applied to the dummy word line may be different from a level of a voltage applied to the general word line, and thus it may be possible to reduce an influence of a non-uniform channel width between the lower and upper channels LCH and UCH on an operation of the memory device.

Meanwhile, the number of the lower word lines 331 and 332 penetrated by the lower channel LCH is less than the number of the upper word lines 333 to 338 penetrated by the upper channel UCH in the region A2. However, embodiments of the present disclosure are not limited thereto. In certain embodiments, the number of the lower word lines penetrated by the lower channel LCH may be equal to or more than the number of the upper word lines penetrated by the upper channel UCH. In addition, structural features and connection relation of the channel structure CH disposed in the second cell region CELL2 may be substantially the same as those of the channel structure CH disposed in the first cell region CELL1.

In the bit line bonding region BLBA, a first through-electrode THV1 may be provided in the first cell region CELL1, and a second through-electrode THV2 may be provided in the second cell region CELL2. As illustrated in FIG. 14, the first through-electrode THV1 may penetrate the common source line 320 and the plurality of word lines 330. In certain embodiments, the first through-electrode THV1 may further penetrate the second substrate 310. The first through-electrode THV1 may include a conductive material. Alternatively, the first through-electrode THV1 may include a conductive material surrounded by an insulating material. The second through-electrode THV2 may have a substantially similar and/or the same shape and structure as the first through-electrode THV1.

In some embodiments, the first through-electrode THV1 and the second through-electrode THV2 may be electrically connected to each other through a first through-metal pattern 372d and a second through-metal pattern 472d. The first through-metal pattern 372d may be formed at a bottom end of the first upper chip including the first cell region CELL1, and the second through-metal pattern 472d may be formed at a top end of the second upper chip including the second cell region CELL2. The first through-electrode THV1 may be electrically connected to the first metal line 350c and the second metal line 360c. A lower via 371d may be formed between the first through-electrode THV1 and the first through-metal pattern 372d, and an upper via 471d may be formed between the second through-electrode THV2 and the second through-metal pattern 472d. The first through-metal pattern 372d and the second through-metal pattern 472d may be connected to each other by the bonding method.

In addition, in the bit line bonding region BLBA, an upper metal pattern 252 may be formed in an uppermost metal layer of the peripheral circuit region PERI, and an upper metal pattern 392 having a substantially similar and/or the same shape as the upper metal pattern 252 may be formed in an uppermost metal layer of the first cell region CELL1. The upper metal pattern 392 of the first cell region CELL1 and the upper metal pattern 252 of the peripheral circuit region PERI may be electrically connected to each other by the bonding method. In the bit line bonding region BLBA, the bit line 360c may be electrically connected to a page buffer included in the peripheral circuit region PERI. For example, some of the circuit elements 220c of the peripheral circuit region PERI may constitute the page buffer, and the bit line 360c may be electrically connected to the circuit elements 220c constituting the page buffer through an upper bonding metal pattern 370c of the first cell region CELL1 and an upper bonding metal pattern 270c of the peripheral circuit region PERI.

Continuing to refer to FIG. 14, in the word line bonding region WLBA, the word lines 330 of the first cell region CELL1 may extend in a second direction (e.g., an X-axis direction) parallel to the top surface of the second substrate 310 and may be connected to a plurality of cell contact plugs 340 (e.g., a first cell contact plug 341, a second cell contact plug 342, a third cell contact plug 343, a fourth cell contact plug 344, a fifth cell contact plug 345, a sixth cell contact plug 346, and a seventh cell contact plug 347). First metal lines 350b and second metal lines 360b may be sequentially connected onto the plurality of cell contact plugs 340 connected to the word lines 330. In the word line bonding region WLBA, the plurality of cell contact plugs 340 may be connected to the peripheral circuit region PERI through upper bonding metal patterns 370b of the first cell region CELL1 and upper bonding metal patterns 270b of the peripheral circuit region PERI.

The plurality of cell contact plugs 340 may be electrically connected to a row decoder included in the peripheral circuit region PERI. For example, some of the circuit elements 220b of the peripheral circuit region PERI may constitute the row decoder, and the plurality of cell contact plugs 340 may be electrically connected to the circuit elements 220b constituting the row decoder through the upper bonding metal patterns 370b of the first cell region CELL1 and the upper bonding metal patterns 270b of the peripheral circuit region PERI. In some embodiments, an operating voltage of the circuit elements 220b constituting the row decoder may be different from an operating voltage of the circuit elements 220c constituting the page buffer. For example, the operating voltage of the circuit elements 220c constituting the page buffer may be greater than the operating voltage of the circuit elements 220b constituting the row decoder.

Likewise, in the word line bonding region WLBA, the plurality of word lines 430 of the second cell region CELL2 may extend in the second direction (e.g., the X-axis direction) parallel to the top surface of the third substrate 410 and may be connected to a plurality of cell contact plugs 440 (e.g., a first cell contact plug 441, a second cell contact plug 442, a third cell contact plug 443, a fourth cell contact plug 444, a fifth cell contact plug 445, a sixth cell contact plug 446, and a seventh cell contact plug 447). The plurality of cell contact plugs 440 may be connected to the peripheral circuit region PERI through an upper metal pattern of the second cell region CELL2 and lower and upper metal patterns and a cell contact plug 348 of the first cell region CELL1.

In the word line bonding region WLBA, the upper bonding metal patterns 370b may be formed in the first cell region CELL1, and the upper bonding metal patterns 270b may be formed in the peripheral circuit region PERI. The upper bonding metal patterns 370b of the first cell region CELL1 and the upper bonding metal patterns 270b of the peripheral circuit region PERI may be electrically connected to each other by the bonding method. The upper bonding metal patterns 370b and the upper bonding metal patterns 270b may be formed of aluminum, copper, or tungsten.

In the external pad bonding region PA, a lower metal pattern 371e may be formed in a lower portion of the first cell region CELL1, and an upper metal pattern 472a may be formed in an upper portion of the second cell region CELL2. The lower metal pattern 371e of the first cell region CELL1 and the upper metal pattern 472a of the second cell region CELL2 may be connected to each other by the bonding method in the external pad bonding region PA. Likewise, an upper metal pattern 372a may be formed in an upper portion of the first cell region CELL1, and an upper metal pattern 272a may be formed in an upper portion of the peripheral circuit region PERI. The upper metal pattern 372a of the first cell region CELL1 and the upper metal pattern 272a of the peripheral circuit region PERI may be connected to each other by the bonding method.

Common source line contact plugs 380 and 480 may be disposed in the external pad bonding region PA. The common source line contact plugs 380 and 480 may be formed of a conductive material such as, but not limited to, a metal, a metal compound, and/or doped polysilicon. The common source line contact plug 380 of the first cell region CELL1 may be electrically connected to the common source line 320, and the common source line contact plug 480 of the second cell region CELL2 may be electrically connected to the common source line 420. A first metal line 350a and a second metal line 360a may be sequentially stacked on the common source line contact plug 380 of the first cell region CELL1, and a first metal line 450a and a second metal line 460a may be sequentially stacked on the common source line contact plug 480 of the second cell region CELL2.

I/O pads (e.g., a first I/O pad 205, a second I/O pad 405, and a third I/O pad 406) may be disposed in the external pad bonding region PA. Referring to FIG. 14, a lower insulating layer 201 may cover a bottom surface of the first substrate 210, and the first I/O pad 205 may be formed on the lower insulating layer 201. The first I/O pad 205 may be connected to at least one of a plurality of the circuit elements 220a disposed in the peripheral circuit region PERI through a first I/O contact plug 203 and may be separated from the first substrate 210 by the lower insulating layer 201. In addition, a side insulating layer may be disposed between the first I/O contact plug 203 and the first substrate 210 to electrically isolate the first I/O contact plug 203 from the first substrate 210.

An upper insulating layer 401 covering a top surface of the third substrate 410 may be formed on the third substrate 410. The second I/O pad 405 and/or the third I/O pad 406 may be disposed on the upper insulating layer 401. The second I/O pad 405 may be connected to at least one of the plurality of circuit elements 220a disposed in the peripheral circuit region PERI through second I/O contact plugs 403 and 303, and the third I/O pad 406 may be connected to at least one of the plurality of circuit elements 220a disposed in the peripheral circuit region PERI through third I/O contact plugs 404 and 304.

In some embodiments, the third substrate 410 may not be disposed in a region in which the I/O contact plug is disposed. For example, as illustrated in a region B, the third I/O contact plug 404 may be separated from the third substrate 410 in a direction parallel to the top surface of the third substrate 410 and may penetrate an interlayer insulating layer 415 of the second cell region CELL2 so as to be connected to the third I/O pad 406. In such a case, the third I/O contact plug 404 may be formed by at least one of various processes.

In some embodiments, as illustrated in a region B1, the third I/O contact plug 404 may extend in a third direction (e.g., the Z-axis direction), and a diameter of the third I/O contact plug 404 may become progressively greater toward the upper insulating layer 401. In other words, a diameter of the channel structure CH described in the region A1 may become progressively less toward the upper insulating layer 401, but the diameter of the third I/O contact plug 404 may become progressively greater toward the upper insulating layer 401. For example, the third I/O contact plug 404 may be formed after the second cell region CELL2 and the first cell region CELL1 are bonded to each other by the bonding method.

In certain embodiments, as illustrated in a region B2, the third I/O contact plug 404 may extend in the third direction (e.g., the Z-axis direction), and a diameter of the third I/O contact plug 404 may become progressively less toward the upper insulating layer 401. In other words, like the channel structure CH, the diameter of the third I/O contact plug 404 may become progressively less toward the upper insulating layer 401. For example, the third I/O contact plug 404 may be formed together with the cell contact plugs 440 before the second cell region CELL2 and the first cell region CELL1 are bonded to each other.

In certain embodiments, the I/O contact plug may overlap with the third substrate 410. For example, as illustrated in a region C, the second I/O contact plug 403 may penetrate the interlayer insulating layer 415 of the second cell region CELL2 in the third direction (e.g., the Z-axis direction) and may be electrically connected to the second I/O pad 405 through the third substrate 410. In this case, a connection structure of the second I/O contact plug 403 and the second I/O pad 405 may be realized by various methods.

In some embodiments, as illustrated in a region C1, an opening 408 may be formed to penetrate the third substrate 410, and the second I/O contact plug 403 may be connected directly to the second I/O pad 405 through the opening 408 formed in the third substrate 410. In this case, as illustrated in the region C1, a diameter of the second I/O contact plug 403 may become progressively greater toward the second I/O pad 405. However, embodiments of the present disclosure are not limited thereto, and in certain embodiments, the diameter of the second I/O contact plug 403 may become progressively less toward the second I/O pad 405.

In certain embodiments, as illustrated in a region C2, the opening 408 penetrating the third substrate 410 may be formed, and a contact 407 may be formed in the opening 408. An end of the contact 407 may be connected to the second I/O pad 405, and another end of the contact 407 may be connected to the second I/O contact plug 403. Thus, the second I/O contact plug 403 may be electrically connected to the second I/O pad 405 through the contact 407 in the opening 408. In this case, as illustrated in the region C2, a diameter of the contact 407 may become progressively greater toward the second I/O pad 405, and a diameter of the second I/O contact plug 403 may become progressively less toward the second I/O pad 405. For example, the second I/O contact plug 403 may be formed together with the cell contact plugs 440 before the second cell region CELL2 and the first cell region CELL1 are bonded to each other, and the contact 407 may be formed after the second cell region CELL2 and the first cell region CELL1 are bonded to each other.

In certain embodiments illustrated in a region C3, a stopper 409 may further be formed on a bottom end of the opening 408 of the third substrate 410, as compared with the embodiments of the region C2. The stopper 409 may be a metal line formed in the same layer as the common source line 420. Alternatively, the stopper 409 may be a metal line formed in the same layer as at least one of the word lines 430. The second I/O contact plug 403 may be electrically connected to the second I/O pad 405 through the contact 407 and the stopper 409.

Like the second and third I/O contact plugs 403 and 404 of the second cell region CELL2, a diameter of each of the second and third I/O contact plugs 303 and 304 of the first cell region CELL1 may become progressively less toward the lower metal pattern 371e or may become progressively greater toward the lower metal pattern 371c.

In some embodiments, a slit 411 may be formed in the third substrate 410. For example, the slit 411 may be formed at a certain position of the external pad bonding region PA. For example, as illustrated in a region D, the slit 411 may be located between the second I/O pad 405 and the cell contact plugs 440 when viewed in a plan view. Alternatively, the second I/O pad 405 may be located between the slit 411 and the cell contact plugs 440 when viewed in a plan view.

In some embodiments, as illustrated in a region D1, the slit 411 may be formed to penetrate the third substrate 410. For example, the slit 411 may be used to prevent the third substrate 410 from being finely cracked when the opening 408 is formed. However, embodiments of the present disclosure are not limited thereto, and in certain embodiments, the slit 411 may be formed to have a depth ranging from about 60% to about 70% of a thickness of the third substrate 410.

In certain embodiments, as illustrated in a region D2, a conductive material 412 may be formed in the slit 411. For example, the conductive material 412 may be used to discharge a leakage current occurring in driving of the circuit elements in the external pad bonding region PA to the outside. In this case, the conductive material 412 may be connected to an external ground line.

In certain embodiments, as illustrated in a region D3, an insulating material 413 may be formed in the slit 411. For example, the insulating material 413 may be used to electrically isolate the second I/O pad 405 and the second I/O contact plug 403 disposed in the external pad bonding region PA from the word line bonding region WLBA. Since the insulating material 413 is formed in the slit 411, it may be possible to prevent a voltage provided through the second I/O pad 405 from affecting a metal layer disposed on the third substrate 410 in the word line bonding region WLBA.

In certain embodiments, the first to third I/O pads 205, 405 and 406 may be selectively formed. For example, the memory device 500 may be realized to include only the first I/O pad 205 disposed on the first substrate 210, to include only the second I/O pad 405 disposed on the third substrate 410, or to include only the third I/O pad 406 disposed on the upper insulating layer 401.

In some embodiments, at least one of the second substrate 310 of the first cell region CELL1 or the third substrate 410 of the second cell region CELL2 may be used as a sacrificial substrate and may be completely or partially removed before or after a bonding process. An additional layer may be stacked after the removal of the substrate. For example, the second substrate 310 of the first cell region CELL1 may be removed before or after the bonding process of the peripheral circuit region PERI and the first cell region CELL1, and then, an insulating layer covering a top surface of the common source line 320 or a conductive layer for connection may be formed. Likewise, the third substrate 410 of the second cell region CELL2 may be removed before or after the bonding process of the first cell region CELL1 and the second cell region CELL2, and then, the upper insulating layer 401 covering a top surface of the common source line 420 or a conductive layer for connection may be formed.

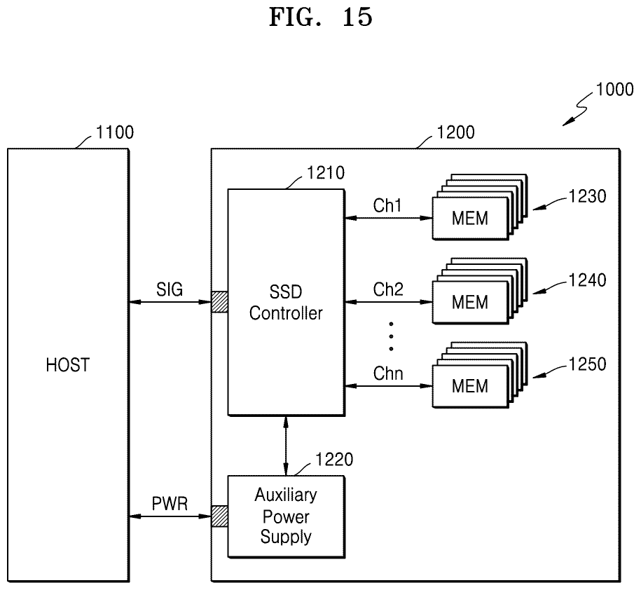

FIG. 15 is a block diagram illustrating an example in which a memory device, according to embodiments, is applied to a solid-state drive (SSD) system 1000.

Referring to FIG. 15, the SSD system 1000 may include a host 1100 and a SSD 1200. SSD 1200 may be configured to transmit/receive signals to/from the host 1100 through a signal connector and/or receive power inputs from a power connector. The SSD 1200 may include an SSD controller 1210, an auxiliary power supply 1220, and memory devices (e.g., a first memory device 1230, a second memory device 1240, and a third memory device 1250). The first to third memory devices 1230, 1240, and 1250 may include a vertical stack NAND flash memory device. In such a case, the SSD 1200 may be implemented based on the embodiments described above with reference to FIGS. 1 to 14.

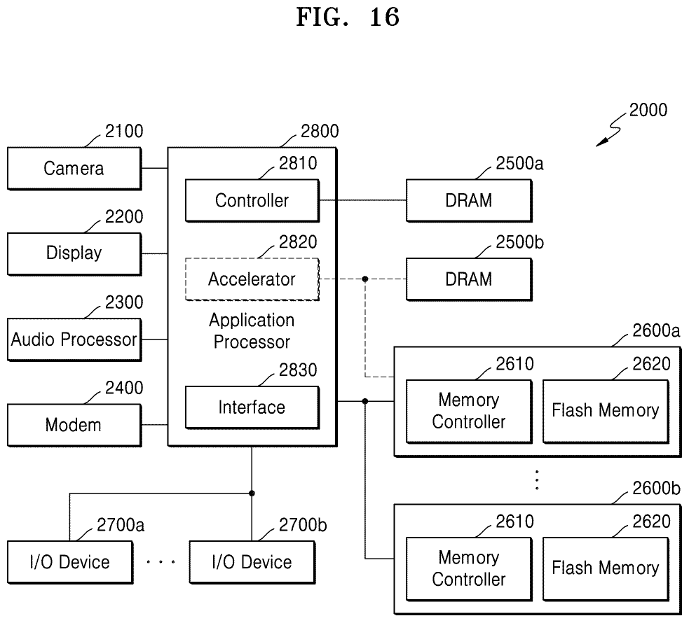

FIG. 16 is a block diagram of a system 2000 for describing an electronic device including a memory device, according to embodiments.

Referring to FIG. 16, the system 2000 may include a camera 2100, a display 2200, an audio processor 2300, a modem 2400, dynamic random access memories (DRAM) (e.g., a first DRAM 2500a and a second DRAM 2500b), flash memories (e.g., a first flash memory 2600a and a second flash memory 2600b), I/O devices (e.g., a first I/O device 2700a and a second I/O device 2700b), and an application processor (AP) 2800. The system 2000 may be implemented as, but not limited to, a laptop computer, a mobile phone, a smart phone, a tablet personal computer (PC), a wearable device, a healthcare device, or an Internet of Things (IoT) device. In addition, the system 2000 may be implemented as a server or a personal computer.

The camera 2100 may be configured to capture still images and/or videos under control of users, and may be configured to store the still images and/or video data captured and/or transfer the still images and/or video data to the display 2200. The audio processor 2300 may be configured to process audio data included in the first and second flash memories 2600a and 2600b and/or contents of a network. The modem 2400 may be configured to modulate and/or transmit signals for wired and/or wireless data transmission, and/or may demodulate and/or restore signals to the original signals at a receiving side. The first and second I/O devices 2700a and 2700b may include devices configured to provide digital input and/or output functions, such as, but not limited to, a universal serial bus (USB), a storage device, a digital camera, a secure digital (SD) card, a digital versatile disc (DVD), a network adapter, a touch screen, or the like.

The AP 2800 may be configured to control general operations of the system 2000. The AP 2800 may include a controller 2810, an accelerator block (or an accelerator chip) 2820, and an interface 2830. The AP 2800 may be configured to control the display 2200 such that some of the contents stored in the first and second flash memories 2600a and 2600b is displayed on the display 2200. When a user input is received through the first and second I/O devices 2700a and 2700b, the AP 2800 may perform a control operation corresponding to the user input. The AP 2800 may include an accelerator block that may be and/or may include a dedicated circuit for artificial intelligence (AI) data calculation. Alternatively or additionally, the accelerator chip 2820 may be provided separately from the AP 2800. The second DRAM 2500b may be additionally mounted in the accelerator block or the accelerator chip 2820. An accelerator, which may be configured to dedicatedly perform certain functions of the AP 2800, may include a graphics processing unit (GPU) that that may be configured to dedicatedly perform graphic data processing, a neural processing unit (NPU) that may be configured to dedicatedly perform AI calculation and inference, and/or a data processing unit (DPU) that may be a dedicated block configured for data communication (e.g., transmission and/or reception). In an embodiment, an image captured through the camera 2100 by the user may be signal-processed and/or stored in the second DRAM 2500b, and the accelerator block and/or the accelerator chip 2820 may perform an AI data operation by using the data stored in the second DRAM 2500b and a function used for inference.

The system 2000 may include the first and second DRAMs 2500a and 2500b. The AP 2800 may be configured to control the first and second DRAMs 2500a and 2500b through command and control conforming to Joint Electron Device Engineering Council (JEDEC) standard specifications and mode resistor (MRS) setting, for example, and/or may be configured to set a DRAM interface protocol and perform communication to use manufacturer-unique functions such as, but not limited to, a low voltage/a high rate/reliability and cyclic redundancy check (CRC)/error correction code (ECC) functions. For example, the AP 2800 may be configured to communicate with the first DRAM 2500a through an interface conforming to the JEDEC standard protocols (e.g., low power double data rate 4 (LPDDR4), low power double data rate 5 (LPDDR5), or the like), and the accelerator block and/or the accelerator chip 2820 may be configured to set new DRAM interface protocols and perform communication to control the second DRAM 2500b for accelerator in a bandwidth of a frequency higher than a bandwidth of a frequency of the first DRAM 2500a.

Although FIG. 16 only illustrates the first and second DRAMs 2500 and 2500b, the present disclosure is not limited thereto, and any memory such as, but not limited to, a phase-change random access memory (PRAM), a static random access memory (SRAM), a magnetic random access memory (MRAM), a resistive random access memory (RRAM), a ferroelectric random access memory (FRAM), or Hybrid RAM may be used as long as the memory fulfills conditions of a bandwidth, a response width, and a voltage of the AP 2800 and/or the accelerator chip 2820. The first and second DRAMs 2500a and 2500b may have a latency and/or bandwidths that may be relatively less than those of the first and second I/O devices 2700a and 2700b and/or the first and second flash memories 2600a and 2600b. The first and second DRAMs 2500a and 2500b may be initialized when the system 2000 is powered-on, and may be loaded with an operation system and application data, therefore may be used as a temporary storage for the operation system and application data and/or a room for performing various software codes.

The first and second DRAMs 2500a and 2500b may perform operations that may include, but may not be limited to, fundamental arithmetic operations (e.g., addition, subtraction, multiplication, division), vector operations, address operations, Fast Fourier Transform (FFT) operations, or the like. Also, a function of a mathematical function for execution used for inference may be performed in the first and second DRAMs 2500a and 2500b. As used herein, inference may be performed in a deep-leaning algorithm using artificial neural network. The deep learning algorithm may include a training process to train a model by using various kinds of data and/or an inference process to recognize the data by using the model that has been trained.

The system 2000 may include a plurality of storages and/or the plurality of flash memories 2600a and 2600b having a greater capacity than a capacity of the first and second DRAMs 2500a and 2500b. The accelerator block and/or the accelerator chip 2820 may be configured to perform the training process and AI data operation by using the first and second flash memories 2600a and 2600b. In an embodiment, the first and second flash memories 2600a and 2600b include a memory controller 2610 and a flash memory 2620, and may be configured to perform, in a relatively efficient manner, the training process and inference AI data operation performed by the AP 2800 and/or the accelerator chip 2820 by using an operation device provided in the memory controller 2610. The first and second flash memories 2600a and 2600b may be configured to process photos and/or images shot (captured) by the camera 2100 and/or data transmitted through a data network. For example, the first and second flash memories 2600a and 2600b may be configured to store augmented reality/virtual reality, high definition (HD), ultra-high definition (UHD) data, or the like.

In the system 2000, the first and second flash memories 2600a and 2600b may include the memory device described with reference to FIGS. 1 to 15. The memory device may include the first pass transistor circuit and the second pass transistor circuit connected to each of the plurality of memory blocks. Each of the plurality of memory blocks may include a plurality of cell strings connected between a P-type substrate and a plurality of bit lines and selected by a string selection line. The first pass transistor circuit may include the plurality of first pass transistors configured to drive each of the string selection line, the ground selection line, and the plurality of word lines of a corresponding memory block, and the second pass transistor circuit may include a plurality of second pass transistors configured to drive each of the string selection line and the ground selection line of a corresponding memory block. The first pass transistor circuit may be arranged in the pocket P-type well area formed on the P-type substrate, and the second pass transistor may be arranged on the P-type substrate. Through the memory devices in which the second pass transistors are formed on the P-type substrate, signal setup speeds of the signal lines connected to the second pass transistors may be improved, and/or chip sizes may be reduced, when compared to related memory devices. Such memory devices may be advantageously applied to storage media such as, but not limited to, a storage device, a system, or the like.

Embodiments have been disclosed with reference to the drawings and the specification. Although embodiments have been described by using specific terms, the terms are only used to describe the present disclosure and are not used to define meanings or limit the scope of the present disclosure written in the following claims. Therefore, it is to be understood to those skilled in the art that various modifications and other equivalent embodiments may be made based on the present disclosure. Therefore, the technical scope of the present disclosure is to be determined based on the technical spirit of the following claims.

While the present disclosure has been particularly shown and described with reference to embodiments thereof, it is to be understood that various changes in form and details may be made therein without departing from the spirit and scope of the following claims.

1. A memory device, comprising:
a memory block including a plurality of cell strings coupled between a first P-type substrate and a plurality of bit lines, the plurality of cell strings being coupled with a plurality of gate lines including a string selection line, a plurality of word lines, and a ground selection line, the plurality of gate lines being stacked in a vertical direction;
a first pass transistor circuit including a plurality of first pass transistors configured to drive first gate lines from among the plurality of gate lines; and
a second pass transistor circuit including a plurality of second pass transistors configured to drive second gate lines from among the plurality of gate lines,
wherein the first pass transistor circuit is disposed in a pocket P-type well area formed on the first P-type substrate, and
wherein the second pass transistor circuit is disposed on a second P-type substrate.

2. The memory device of claim 1, wherein the second gate lines include at least one of the string selection line or the ground selection line.

3. The memory device of claim 1, wherein the plurality of gate lines further include at least one dummy word line stacked in the vertical direction, and
wherein the second gate lines include the at least one dummy word line.

4. The memory device of claim 3, wherein third gate lines from among the plurality of gate lines are driven by at least one of the first pass transistor circuit and the second pass transistor circuit, and
wherein the third gate lines include at least one of the string selection line, the ground selection line, or the at least one dummy word line.

5. The memory device of claim 1, wherein the first gate lines include the plurality of word lines.

6. The memory device of claim 1, wherein the first P-type substrate and the second P-type substrate are a same substrate.

7. The memory device of claim 1, wherein the first P-type substrate is different from the second P-type substrate.

8. A memory device, comprising:
a memory block including a plurality of cell strings coupled between a first P-type substrate and a plurality of bit lines, the plurality of cell strings being configured to be selected by a string selection line, each of the plurality of cell strings being coupled with a plurality of word lines stacked in a vertical direction;
a first pass transistor circuit including a plurality of first pass transistors configured to drive the string selection line and each of the plurality of word lines; and
a second pass transistor circuit including a plurality of second pass transistors configured to drive the string selection line,
wherein the first pass transistor circuit is disposed in a pocket P-type well area formed on the first P-type substrate,
wherein the second pass transistor circuit is disposed on a second P-type substrate,
wherein the pocket P-type well area is formed in a deep N-type well area formed on the first P-type substrate and is biased with a negative voltage,
wherein the deep N-type well area is biased with a positive voltage, and
wherein the second P-type substrate is biased with a ground voltage.

9. The memory device of claim 8, wherein the first pass transistor circuit and the second pass transistor circuit each are configured to drive a ground selection line coupled with the plurality of cell strings.

10. The memory device of claim 8, wherein the memory block further includes a dummy word line between a ground selection line and the plurality of word lines, and
wherein the plurality of second pass transistors are further configured to drive the dummy word line.

11. The memory device of claim 8, wherein the memory block further includes a dummy word line between the string selection line and the plurality of word lines, and
wherein the plurality of second pass transistors are further configured to drive the dummy word line.

12. A memory device, comprising:
a memory block including a plurality of cell strings coupled between a first P-type substrate and a plurality of bit lines, the plurality of cell strings being coupled with a string selection line, a plurality of word lines, a ground selection line, and a first dummy word line between the string selection line and the plurality of word lines, the plurality of cell strings being stacked in a vertical direction;
a first pass transistor circuit including a plurality of first pass transistors configured to drive each of the string selection line, the plurality of word lines, and the ground selection line; and
a second pass transistor circuit including a plurality of second pass transistors configured to drive each of
the ground selection line and
the first dummy word line,
wherein the first pass transistor circuit is disposed in a pocket P-type well area formed on the first P-type substrate, and
wherein the second pass transistor circuit is disposed on a second P-type substrate.

13. The memory device of claim 12, wherein the pocket P-type well area is formed in a deep N-type well area formed on the first P-type substrate and is biased with a negative voltage,
wherein the deep N-type well area is biased with a positive voltage, and
wherein the second P-type substrate is biased with a ground voltage.

14. The memory device of claim 12, wherein the plurality of second pass transistors are further configured to drive the string selection line of a plurality of gate lines.

15. The memory device of claim 12, wherein the memory block further includes a second dummy word line between the ground selection line and the plurality of word lines, and
wherein the plurality of second pass transistors are further configured to drive the second dummy word line.

16. The memory device of claim 12, wherein the first P-type substrate and the second P-type substrate are a same substrate.

17. The memory device of claim 12, wherein the first P-type substrate is different from the second P-type substrate.

18. A memory device, comprising:
a memory block including a plurality of cell strings coupled between a first P-type substrate and a plurality of bit lines, the plurality of cell strings being coupled with a plurality of gate lines including a string selection line, a plurality of word lines, at least one dummy word line, and a ground selection line, the plurality of gate lines being stacked in a vertical direction;
a first pass transistor circuit including a plurality of first pass transistors configured to drive each of the string selection line, the plurality of word lines, the at least one dummy word line, and the ground selection line; and
a second pass transistor circuit including:
a plurality of second pass transistors configured to drive the at least one dummy word line and
the string selection line,
wherein the first pass transistor circuit is disposed in a pocket P-type well area formed on the first P-type substrate, and
wherein the second pass transistor circuit is disposed on a second P-type substrate.

19. The memory device of claim 18, wherein the pocket P-type well area is formed in a deep N-type well area formed on the first P-type substrate and is biased with a negative voltage,
wherein the deep N-type well area is biased with a positive voltage, and
wherein the second P-type substrate is biased with a ground voltage.

20. The memory device of claim 18, wherein the first P-type substrate and the second P-type substrate are a same substrate.

21-39. (canceled)
